(19) United States
(12) Patent Application Publication
(10) Pub. No.: US 2026/0237878 A1
(43) Pub. Date: Aug. 13, 2026

(54) APPARATUS, SYSTEM, AND METHOD OF A PRINTED CIRCUIT BOARD (PCB) TO WAVEGUIDE TRANSITION

(71) Applicant: MOBILEYE VISION TECHNOLOGIES LTD., Jerusalem (IL)

(72) Inventor: Ofer MARKISH, Ra'anana (IL)

(73) Assignee: MOBILEYE VISION TECHNOLOGIES LTD., Jerusalem (IL)

(21) Appl. No.: 19/471,398

(22) PCT Filed: Apr. 3, 2024
(86) PCT No.: PCT/IB2024/053268

§ 371 Date: Oct. 1, 2025

Related U.S. Application Data
(60) Provisional application No. 63/494,238, filed on Apr. 5, 2023.
(60) Provisional application No. 63/624,069, filed on Jan. 23, 2024.

(51) Int. Cl. H01P 5/10; G01S 7/03; G01S 13/931; H05K 1/02; H05K 1/181

(52) U.S. Cl. CPC H01P 5/10; G01S 7/03; G01S 13/931; H05K 1/0243; H05K 1/0251; H05K 1/181; G01S 2013/93271; H05K 2201/10098

(57) ABSTRACT

A Printed Circuit Board (PCB) may include one or more single-ended PCB traces configured to route single-ended Radio-Frequency (RF) signals between an integrated circuit and one or more waveguides, wherein first ends of the one or more single-ended PCB traces are to be coupled to the integrated circuit; and one or more PCB-to-waveguide transitions configured to couple second ends of the one or more single-ended PCB traces to the one or more waveguides. For example, a PCB-to-waveguide transition may include a PCB probe connected to a second end of a single-ended PCB trace of the one or more single-ended PCB traces, the PCB probe configured to couple RF energy of the single-ended RF signals between the single-ended PCB trace and a waveguide of the one or more waveguides; and a via configured to electrically connect the PCB probe to a ground layer of the PCB.

### CROSS REFERENCE

This application claims the benefit of, and priority from, U.S. Provisional Patent Application No. 63/494,238 entitled “APPARATUS, SYSTEM, AND METHOD OF PCB TO WAVEGUIDE TRANSITION”, filed Apr. 5, 2023, and U.S. Provisional Patent Application No. 63/624,069 entitled “APPARATUS, SYSTEM, AND METHOD OF A PRINTED CIRCUIT BOARD (PCB) TO WAVEGUIDE TRANSITION”, filed Jan. 23, 2024, the entire disclosures of which are incorporated herein by reference.

### BACKGROUND

Various types of devices and systems, for example, radar devices, wireless communication devices, and the like, may be configured to utilize a waveguide technology to transfer signals, e.g., Radio Frequency (RF) signals, between an antenna and circuitry to process the signals.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a vehicle implementing a radar, in accordance with some demonstrative aspects.

FIG. 2 is a schematic block diagram illustration of a robot implementing a radar, in accordance with some demonstrative aspects.

FIG. 3 is a schematic block diagram illustration of a radar apparatus, in accordance with some demonstrative aspects.

FIG. 4 is a schematic block diagram illustration of a Frequency-Modulated Continuous Wave (FMCW) radar apparatus, in accordance with some demonstrative aspects.

FIG. 5 is a schematic illustration of an extraction scheme, which may be implemented to extract range and speed (Doppler) estimations from digital reception radar data values, in accordance with some demonstrative aspects.

FIG. 6 is a schematic illustration of an angle-determination scheme, which may be implemented to determine Angle of Arrival (AoA) information based on an incoming radio signal received by a receive antenna array, in accordance with some demonstrative aspects.

FIG. 7 is a schematic illustration of a Multiple-Input-Multiple-Output (MIMO) radar antenna scheme, which may be implemented based on a combination of Transmit (Tx) and Receive (Rx) antennas, in accordance with some demonstrative aspects.

FIG. 8 is a schematic block diagram illustration of elements of a radar device including a radar frontend and a radar processor, in accordance with some demonstrative aspects.

FIG. 9 is a schematic illustration of a radar system including a plurality of radar devices implemented in a vehicle, in accordance with some demonstrative aspects.

FIG. 10 is a schematic illustration of a waveguide (WG) based (WG-based) structure and a printed-antenna-based structure, to illustrate one or more technical aspects, which may be addressed in accordance with some demonstrative aspects.

FIG. 11 is a schematic illustration of a WG-based structure including Printed Circuit Board (PCB) to WG-narrow-side transitions, and a WG-based structure including PCB to WG-wide-side transitions, to illustrate one or more technical aspects, which may be addressed in accordance with some demonstrative aspects.

FIG. 12 is a schematic illustration of a PCB to WG-wide-side transition, to illustrate one or more technical aspects, which may be addressed in accordance with some demonstrative aspects.

FIG. 13 is a schematic illustration of a PCB to WG-narrow-side transition to illustrate one or more technical aspects, which may be addressed in accordance with some demonstrative aspects.

FIG. 14 is a schematic illustration of a system, in accordance with some demonstrative aspects.

FIG. 15 is a schematic illustration of a PCB-to-WG transition, in accordance with some demonstrative aspects.

FIG. 16 is a schematic illustration of a PCB-to-WG transition, in accordance with some demonstrative aspects.

FIG. 17 is a schematic illustration of graphs depicting matching curves of a PCB-to-narrow-waveguide-side transition, in accordance with some demonstrative aspects.

FIG. 18 is a schematic illustration of a product of manufacture, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

The words “exemplary” and “demonstrative” are used herein to mean “serving as an example, instance, demonstration, or illustration”. Any aspect, or design described herein as “exemplary” or “demonstrative” is not necessarily to be construed as preferred or advantageous over other aspects, or designs.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

The phrases “at least one” and “one or more” may be understood to include a numerical quantity greater than or equal to one, e.g., one, two, three, four, [ . . . ], etc. The phrase “at least one of” with regard to a group of elements may be used herein to mean at least one element from the group consisting of the elements. For example, the phrase “at least one of” with regard to a group of elements may be used herein to mean one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and/or may represent any information as understood in the art.

The terms “processor” or “controller” may be understood to include any kind of technological entity that allows handling of any suitable type of data and/or information. The data and/or information may be handled according to one or more specific functions executed by the processor or controller. Further, a processor or a controller may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), and the like, or any combination thereof. Any other kind of implementation of the respective functions, which will be described below in further detail, may also be understood as a processor, controller, or logic circuit. It is understood that any two (or more) processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” is understood as a computer-readable medium (e.g., a non-transitory computer-readable medium) in which data or information can be stored for retrieval. References to “memory” may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” may be used to refer to any type of executable instruction and/or logic, including firmware.

A “vehicle” may be understood to include any type of driven object. By way of example, a vehicle may be a driven object with a combustion engine, an electric engine, a reaction engine, an electrically driven object, a hybrid driven object, or a combination thereof. A vehicle may be, or may include, an automobile, a bus, a mini bus, a van, a truck, a mobile home, a vehicle trailer, a motorcycle, a bicycle, a tricycle, a train locomotive, a train wagon, a moving robot, a personal transporter, a boat, a ship, a submersible, a submarine, a drone, an aircraft, a rocket, among others.

A “ground vehicle” may be understood to include any type of vehicle, which is configured to traverse the ground, e.g., on a street, on a road, on a track, on one or more rails, off-road, or the like.

An “autonomous vehicle” may describe a vehicle capable of implementing at least one navigational change without driver input. A navigational change may describe or include a change in one or more of steering, braking, acceleration/deceleration, or any other operation relating to movement, of the vehicle. A vehicle may be described as autonomous even in case the vehicle is not fully autonomous, for example, fully operational with driver or without driver input. Autonomous vehicles may include those vehicles that can operate under driver control during certain time periods, and without driver control during other time periods. Additionally or alternatively, autonomous vehicles may include vehicles that control only some aspects of vehicle navigation, such as steering, e.g., to maintain a vehicle course between vehicle lane constraints, or some steering operations under certain circumstances, e.g., not under all circumstances, but may leave other aspects of vehicle navigation to the driver, e.g., braking or braking under certain circumstances. Additionally or alternatively, autonomous vehicles may include vehicles that share the control of one or more aspects of vehicle navigation under certain circumstances, e.g., hands-on, such as responsive to a driver input; and/or vehicles that control one or more aspects of vehicle navigation under certain circumstances, e.g., hands-off, such as independent of driver input. Additionally or alternatively, autonomous vehicles may include vehicles that control one or more aspects of vehicle navigation under certain circumstances, such as under certain environmental conditions, e.g., spatial areas, roadway conditions, or the like. In some aspects, autonomous vehicles may handle some or all aspects of braking, speed control, velocity control, steering, and/or any other additional operations, of the vehicle. An autonomous vehicle may include those vehicles that can operate without a driver. The level of autonomy of a vehicle may be described or determined by the Society of Automotive Engineers (SAE) level of the vehicle, e.g., as defined by the SAE, for example in SAE J3016 2018: Taxonomy and definitions for terms related to driving automation systems for on road motor vehicles, or by other relevant professional organizations. The SAE level may have a value ranging from a minimum level, e.g., level 0 (illustratively, substantially no driving automation), to a maximum level, e.g., level 5 (illustratively, full driving automation).

An “assisted vehicle” may describe a vehicle capable of informing a driver or occupant of the vehicle of sensed data or information derived therefrom.

The phrase “vehicle operation data” may be understood to describe any type of feature related to the operation of a vehicle. By way of example, “vehicle operation data” may describe the status of the vehicle, such as, the type of tires of the vehicle, the type of vehicle, and/or the age of the manufacturing of the vehicle. More generally, “vehicle operation data” may describe or include static features or static vehicle operation data (illustratively, features or data not changing over time). As another example, additionally or alternatively, “vehicle operation data” may describe or include features changing during the operation of the vehicle, for example, environmental conditions, such as weather conditions or road conditions during the operation of the vehicle, fuel levels, fluid levels, operational parameters of the driving source of the vehicle, or the like. More generally, “vehicle operation data” may describe or include varying features or varying vehicle operation data (illustratively, time varying features or data).

Some aspects may be used in conjunction with various devices and systems, for example, a radar sensor, a radar device, a radar system, a vehicle, a vehicular system, an autonomous vehicular system, a vehicular communication system, a vehicular device, an airborne platform, a waterborne platform, road infrastructure, sports-capture infrastructure, city monitoring infrastructure, static infrastructure platforms, indoor platforms, moving platforms, robot platforms, industrial platforms, a sensor device, a User Equipment (UE), a Mobile Device (MD), a wireless station (STA), a sensor device, a non-vehicular device, a mobile or portable device, and the like.

Some aspects may be used in conjunction with Radio Frequency (RF) systems, radar systems, vehicular radar systems, autonomous systems, robotic systems, detection systems, or the like.

Some demonstrative aspects may be used in conjunction with an RF frequency in a frequency band having a starting frequency above 10 Gigahertz (GHz), for example, a frequency band having a starting frequency between 10 GHz and 120 GHz. For example, some demonstrative aspects may be used in conjunction with an RF frequency having a starting frequency above 30 GHz, for example, above 45 GHZ, e.g., above 60 GHz. For example, some demonstrative aspects may be used in conjunction with an automotive radar frequency band, e.g., a frequency band between 76 GHz and 81 GHz. However, other aspects may be implemented utilizing any other suitable frequency bands, for example, a frequency band above 140 GHz, a frequency band of 300 GHz, a sub Terahertz (THz) band, a THz band, an Infra-Red (IR) band, and/or any other frequency band.

As used herein, the term “circuitry” may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality. In some aspects, some functions associated with the circuitry may be implemented by one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g., radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and/or the like. Logic may be executed by one or more processors using memory, e.g., registers, buffers, stacks, and the like, coupled to the one or more processors, e.g., as necessary to execute the logic.

The term “communicating” as used herein with respect to a signal includes transmitting the signal and/or receiving the signal. For example, an apparatus, which is capable of communicating a signal, may include a transmitter to transmit the signal, and/or a receiver to receive the signal. The verb communicating may be used to refer to the action of transmitting or the action of receiving. In one example, the phrase “communicating a signal” may refer to the action of transmitting the signal by a transmitter, and may not necessarily include the action of receiving the signal by a receiver. In another example, the phrase “communicating a signal” may refer to the action of receiving the signal by a receiver, and may not necessarily include the action of transmitting the signal by a transmitter.

The term “antenna”, as used herein, may include any suitable configuration, structure, and/or arrangement of one or more antenna elements, components, units, assemblies, and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a MIMO (Multiple-Input Multiple-Output) array antenna, a single element antenna, a set of switched beam antennas, and/or the like. In one example, an antenna may be implemented as a separate element or an integrated element, for example, as an on-module antenna, an on-chip antenna, or according to any other antenna architecture.

Some demonstrative aspects are described herein with respect to RF radar signals. However, other aspects may be implemented with respect to, or in conjunction with, any other radar signals, wireless signals, IR signals, acoustic signals, optical signals, wireless communication signals, communication scheme, network, standard, and/or protocol. For example, some demonstrative aspects may be implemented with respect to systems, e.g., Light Detection Ranging (LiDAR) systems, and/or sonar systems, utilizing light and/or acoustic signals.

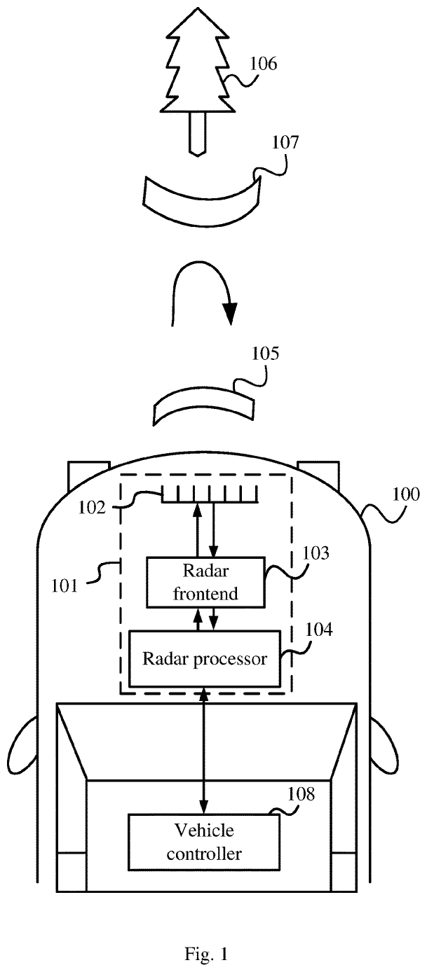

Reference is now made to FIG. 1, which schematically illustrates a block diagram of a vehicle 100 implementing a radar, in accordance with some demonstrative aspects.

In some demonstrative aspects, vehicle 100 may include a car, a truck, a motorcycle, a bus, a train, an airborne vehicle, a waterborne vehicle, a cart, a golf cart, an electric cart, a road agent, or any other vehicle.

In some demonstrative aspects, vehicle 100 may include a radar device 101, e.g., as described below. For example, radar device 101 may include a radar detecting device, a radar sensing device, a radar sensor, or the like, e.g., as described below.

In some demonstrative aspects, radar device 101 may be implemented as part of a vehicular system, for example, a system to be implemented and/or mounted in vehicle 100.

In one example, radar device 101 may be implemented as part of an autonomous vehicle system, an automated driving system, an assisted vehicle system, a driver assistance and/or support system, and/or the like.

For example, radar device 101 may be installed in vehicle 100 for detection of nearby objects, e.g., for autonomous driving.

In some demonstrative aspects, radar device 101 may be configured to detect targets in a vicinity of vehicle 100, e.g., in a far vicinity and/or a near vicinity, for example, using RF and analog chains, capacitor structures, large spiral transformers and/or any other electronic or electrical elements, e.g., as described below.

In one example, radar device 101 may be mounted onto, placed, e.g., directly, onto, or attached to, vehicle 100.

In some demonstrative aspects, vehicle 100 may include a plurality of radar aspects, vehicle 100 may include a single radar device 101.

In some demonstrative aspects, vehicle 100 may include a plurality of radar devices 101, which may be configured to cover a field of view of 360 degrees around vehicle 100.

In other aspects, vehicle 100 may include any other suitable count, arrangement, and/or configuration of radar devices and/or units, which may be suitable to cover any other field of view, e.g., a field of view of less than 360 degrees.

In some demonstrative aspects, radar device 101 may be implemented as a component in a suite of sensors used for driver assistance and/or autonomous vehicles, for example, due to the ability of radar to operate in nearly all-weather conditions.

In some demonstrative aspects, radar device 101 may be configured to support autonomous vehicle usage, e.g., as described below.

In one example, radar device 101 may determine a class, a location, an orientation, a velocity, an intention, a perceptional understanding of the environment, and/or any other information corresponding to an object in the environment.

In another example, radar device 101 may be configured to determine one or more parameters and/or information for one or more operations and/or tasks, e.g., path planning, and/or any other tasks.

In some demonstrative aspects, radar device 101 may be configured to map a scene by measuring targets' echoes (reflectivity) and discriminating them, for example, mainly in range, velocity, azimuth and/or elevation, e.g., as described below.

In some demonstrative aspects, radar device 101 may be configured to detect, and/or sense, one or more objects, which are located in a vicinity, e.g., a far vicinity and/or a near vicinity, of the vehicle 100, and to provide one or more parameters, attributes, and/or information with respect to the objects.

In some demonstrative aspects, the objects may include road users, such as other vehicles, pedestrians; road objects and markings, such as traffic signs, traffic lights, lane markings, road markings, road elements, e.g., a pavement-road meeting, a road edge, a road profile, road roughness (or smoothness); general objects, such as a hazard, e.g., a tire, a box, a crack in the road surface; and/or the like.

In some demonstrative aspects, the one or more parameters, attributes and/or information with respect to the object may include a range of the objects from the vehicle 100, an angle of the object with respect to the vehicle 100, a location of the object with respect to the vehicle 100, a relative speed of the object with respect to vehicle 100, and/or the like.

In some demonstrative aspects, radar device 101 may include a Multiple Input Multiple Output (MIMO) radar device 101, e.g., as described below.

In one example, the MIMO radar device may be configured to utilize “spatial filtering” processing, for example, beamforming and/or any other mechanism, for one or both of Transmit (Tx) signals and/or Receive (Rx) signals.

Some demonstrative aspects are described below with respect to a radar device, e.g., radar device 101, implemented as a MIMO radar. However, in other aspects, radar device 101 may be implemented as any other type of radar utilizing a plurality of antenna elements, e.g., a Single Input Multiple Output (SIMO) radar or a Multiple Input Single output (MISO) radar.

Some demonstrative aspects may be implemented with respect to a radar device, e.g., radar device 101, implemented as a MIMO radar, e.g., as described below. However, in other aspects, radar device 101 may be implemented as any other type of radar, for example, an Electronic Beam Steering radar, a Synthetic Aperture Radar (SAR), adaptive and/or cognitive radars that change their transmission according to the environment and/or ego state, a reflect array radar, or the like.

In some demonstrative aspects, radar device 101 may include an antenna arrangement 102, a radar frontend 103 configured to communicate radar signals via the antenna arrangement 102, and a radar processor 104 configured to generate radar information based on the radar signals, e.g., as described below.

In some demonstrative aspects, radar processor 104 may be configured to process radar information of radar device 101 and/or to control one or more operations of radar device 101, e.g., as described below.

In some demonstrative aspects, radar processor 104 may include, or may be implemented, partially or entirely, by circuitry and/or logic, e.g., one or more processors including circuitry and/or logic, memory circuitry and/or logic. Additionally or alternatively, one or more functionalities of radar processor 104 may be implemented by logic, which may be executed by a machine and/or one or more processors, e.g., as described below.

In one example, radar processor 104 may include at least one memory, e.g., coupled to the one or more processors, which may be configured, for example, to store, e.g., at least temporarily, at least some of the information processed by the one or more processors and/or circuitry, and/or which may be configured to store logic to be utilized by the processors and/or circuitry.

In other aspects, radar processor 104 may be implemented by one or more additional or alternative elements of vehicle 100.

In some demonstrative aspects, radar frontend 103 may include, for example, one or more (radar) transmitters, and a one or more (radar) receivers, e.g., as described below.

In some demonstrative aspects, antenna arrangement 102 may include a plurality of antennas to communicate the radar signals. For example, antenna arrangement 102 may include multiple transmit antennas in the form of a transmit antenna array, and multiple receive antennas in the form of a receive antenna array. In another example, antenna arrangement 102 may include one or more antennas used both as transmit and receive antennas. In the latter case, the radar frontend 103, for example, may include a duplexer or a circulator, e.g., a circuit to separate transmitted signals from received signals.

In some demonstrative aspects, as shown in FIG. 1, the radar frontend 103 and the antenna arrangement 102 may be controlled, e.g., by radar processor 104, to transmit a radio transmit signal 105.

In some demonstrative aspects, as shown in FIG. 1, the radio transmit signal 105 may be reflected by an object 106, resulting in an echo 107.

In some demonstrative aspects, the radar device 101 may receive the echo 107, e.g., via antenna arrangement 102 and radar frontend 103, and radar processor 104 may generate radar information, for example, by calculating information about position, radial velocity (Doppler), and/or direction of the object 106, e.g., with respect to vehicle 100.

In some demonstrative aspects, radar processor 104 may be configured to provide the radar information to a vehicle controller 108 of the vehicle 100, e.g., for autonomous driving of the vehicle 100.

In some demonstrative aspects, at least part of the functionality of radar processor 104 may be implemented as part of vehicle controller 108. In other aspects, the functionality of radar processor 104 may be implemented as part of any other element of radar device 101 and/or vehicle 100. In other aspects, radar processor 104 may be implemented, as a separate part of, or as part of any other element of radar device 101 and/or vehicle 100.

In some demonstrative aspects, vehicle controller 108 may be configured to control one or more functionalities, modes of operation, components, devices, systems, and/or elements of vehicle 100.

In some demonstrative aspects, vehicle controller 108 may be configured to control one or more vehicular systems of vehicle 100, e.g., as described below.

In some demonstrative aspects, the vehicular systems may include, for example, a steering system, a braking system, a driving system, and/or any other system of the vehicle 100.

In some demonstrative aspects, vehicle controller 108 may configured to control radar device 101, and/or to process one or parameters, attributes and/or information from radar device 101.

In some demonstrative aspects, vehicle controller 108 may be configured, for example, to control the vehicular systems of the vehicle 100, for example, based on radar information from radar device 101 and/or one or more other sensors of the vehicle 100, e.g., Light Detection and Ranging (LIDAR) sensors, camera sensors, and/or the like.

In one example, vehicle controller 108 may control the steering system, the braking system, and/or any other vehicular systems of vehicle 100, for example, based on the information from radar device 101, e.g., based on one or more objects detected by radar device 101.

In other aspects, vehicle controller 108 may be configured to control any other additional or alternative functionalities of vehicle 100.

Some demonstrative aspects are described herein with respect to a radar device 101 implemented in a vehicle, e.g., vehicle 100. In other aspects a radar device, e.g., radar device 101, may be implemented as part of any other element of a traffic system or network, for example, as part of a road infrastructure, and/or any other element of a traffic network or system. Other aspects may be implemented with respect to any other system, environment, and/or apparatus, which may be implemented in any other object, environment, location, or place. For example, radar device 101 may be part of a non-vehicular device, which may be implemented, for example, in an indoor location, a stationary infrastructure outdoors, or any other location.

In some demonstrative aspects, radar device 101 may be configured to support security usage. In one example, radar device 101 may be configured to determine a nature of an operation, e.g., a human entry, an animal entry, an environmental movement, and the like, to identity a threat level of a detected event, and/or any other additional or alternative operations.

Some demonstrative aspects may be implemented with respect to any other additional or alternative devices and/or systems, for example, for a robot, e.g., as described below.

In other aspects, radar device 101 may be configured to support any other usages and/or applications.

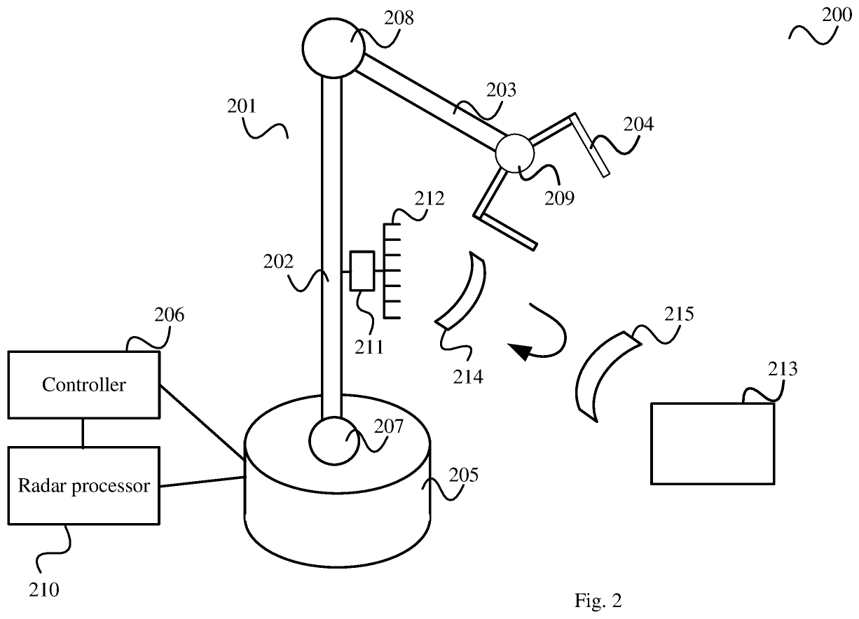

Reference is now made to FIG. 2, which schematically illustrates a block diagram of a robot 200 implementing a radar, in accordance with some demonstrative aspects.

In some demonstrative aspects, robot 200 may include a robot arm 201. The robot 200 may be implemented, for example, in a factory for handling an object 213, which may be, for example, a part that should be affixed to a product that is being manufactured. The robot arm 201 may include a plurality of movable members, for example, movable members 202, 203, 204, and a support 205. Moving the movable members 202, 203, and/or 204 of the robot arm 201, e.g., by actuation of associated motors, may allow physical interaction with the environment to carry out a task, e.g., handling the object 213.

In some demonstrative aspects, the robot arm 201 may include a plurality of joint elements, e.g., joint elements 207, 208, 209, which may connect, for example, the members 202, 203, and/or 204 with each other, and with the support 205. For example, a joint element 207, 208, 209 may have one or more joints, each of which may provide rotatable motion, e.g., rotational motion, and/or translatory motion, e.g., displacement, to associated members and/or motion of members relative to each other. The movement of the members 202, 203, 204 may be initiated by suitable actuators.

In some demonstrative aspects, the member furthest from the support 205, e.g., member 204, may also be referred to as the end-effector 204 and may include one or more tools, such as, a claw for gripping an object, a welding tool, or the like. Other members, e.g., members 202, 203, closer to the support 205, may be utilized to change the position of the end-effector 204, e.g., in three-dimensional space. For example, the robot arm 201 may be configured to function similarly to a human arm, e.g., possibly with a tool at its end.

In some demonstrative aspects, robot 200 may include a (robot) controller 206 configured to implement interaction with the environment, e.g., by controlling the robot arm's actuators, according to a control program, for example, in order to control the robot arm 201 according to the task to be performed.

In some demonstrative aspects, an actuator may include a component adapted to affect a mechanism or process in response to being driven. The actuator can respond to commands given by the controller 206 (the so-called activation) by performing mechanical movement. This means that an actuator, typically a motor (or electromechanical converter), may be configured to convert electrical energy into mechanical energy when it is activated (i.e. actuated).

In some demonstrative aspects, controller 206 may be in communication with a radar processor 210 of the robot 200.

In some demonstrative aspects, a radar fronted 211 and a radar antenna arrangement 212 may be coupled to the radar processor 210. In one example, radar fronted 211 and/or radar antenna arrangement 212 may be included, for example, as part of the robot arm 201.

In some demonstrative aspects, the radar frontend 211, the radar antenna arrangement 212 and the radar processor 210 may be operable as, and/or may be configured to form, a radar device. For example, antenna arrangement 212 may be configured to perform one or more functionalities of antenna arrangement 102 (FIG. 1), radar frontend 211 may be configured to perform one or more functionalities of radar frontend 103 (FIG. 1), and/or radar processor 210 may be configured to perform one or more functionalities of radar processor 104 (FIG. 1), e.g., as described above.

In some demonstrative aspects, for example, the radar frontend 211 and the antenna arrangement 212 may be controlled, e.g., by radar processor 210, to transmit a radio transmit signal 214.

In some demonstrative aspects, as shown in FIG. 2, the radio transmit signal 214 may be reflected by the object 213, resulting in an echo 215.

In some demonstrative aspects, the echo 215 may be received, e.g., via antenna arrangement 212 and radar frontend 211, and radar processor 210 may generate radar information, for example, by calculating information about position, speed (Doppler) and/or direction of the object 213, e.g., with respect to robot arm 201.

In some demonstrative aspects, radar processor 210 may be configured to provide the radar information to the robot controller 206 of the robot arm 201, e.g., to control robot arm 201. For example, robot controller 206 may be configured to control robot arm 201 based on the radar information, e.g., to grab the object 213 and/or to perform any other operation.

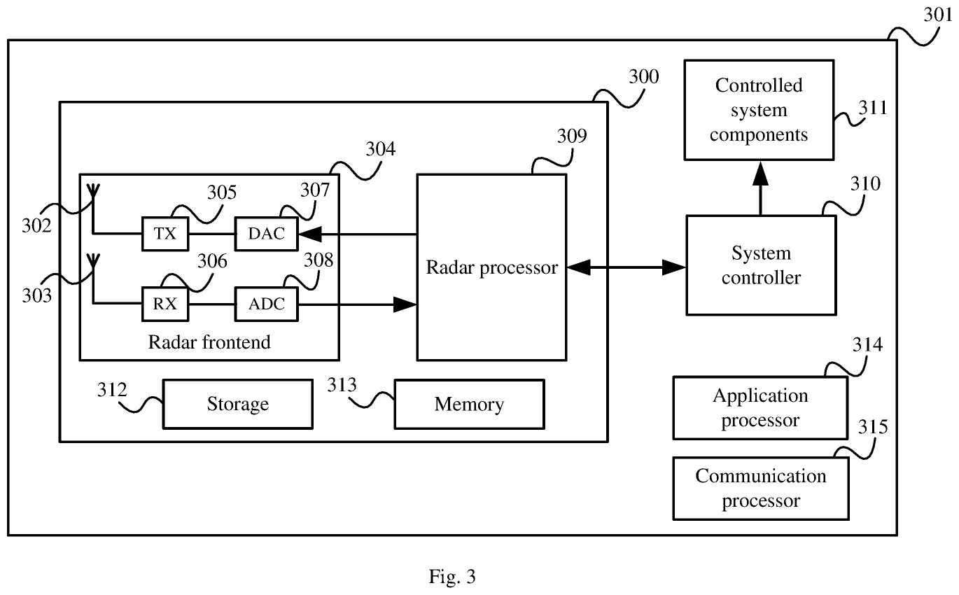

Reference is made to FIG. 3, which schematically illustrates a radar apparatus 300, in accordance with some demonstrative aspects.

In some demonstrative aspects, radar apparatus 300 may be implemented as part of a device or system 301, e.g., as described below.

For example, radar apparatus 300 may be implemented as part of, and/or may configured to perform one or more operations and/or functionalities of, the devices or systems described above with reference to FIG. 1 an/or FIG. 2. In other aspects, radar apparatus 300 may be implemented as part of any other device or system 301.

In some demonstrative aspects, radar device 300 may include an antenna arrangement, which may include one or more transmit antennas 302 and one or more receive antennas 303. In other aspects, any other antenna arrangement may be implemented.

In some demonstrative aspects, radar device 300 may include a radar frontend 304, and a radar processor 309.

In some demonstrative aspects, as shown in FIG. 3, the one or more transmit antennas 302 may be coupled with a transmitter (or transmitter arrangement) 305 of the radar frontend 304; and/or the one or more receive antennas 303 may be coupled with a receiver (or receiver arrangement) 306 of the radar frontend 304, e.g., as described below.

In some demonstrative aspects, transmitter 305 may include one or more elements, for example, an oscillator, a power amplifier and/or one or more other elements, configured to generate radio transmit signals to be transmitted by the one or more transmit antennas 302, e.g., as described below.

In some demonstrative aspects, for example, radar processor 309 may provide digital radar transmit data values to the radar frontend 304. For example, radar frontend 304 may include a Digital-to-Analog Converter (DAC) 307 to convert the digital radar transmit data values to an analog transmit signal. The transmitter 305 may convert the analog transmit signal to a radio transmit signal which is to be transmitted by transmit antennas 302.

In some demonstrative aspects, receiver 306 may include one or more elements, for example, one or more mixers, one or more filters and/or one or more other elements, configured to process, down-convert, radio signals received via the one or more receive antennas 303, e.g., as described below.

In some demonstrative aspects, for example, receiver 306 may convert a radio receive signal received via the one or more receive antennas 303 into an analog receive signal. The radar frontend 304 may include an Analog-to-Digital Converter (ADC) 308 to generate digital radar reception data values based on the analog receive signal. For example, radar frontend 304 may provide the digital radar reception data values to the radar processor 309.

In some demonstrative aspects, radar processor 309 may be configured to process the digital radar reception data values, for example, to detect one or more objects, e.g., in an environment of the device/system 301. This detection may include, for example, the determination of information including one or more of range, speed (Doppler), direction, and/or any other information, of one or more objects, e.g., with respect to the system 301.

In some demonstrative aspects, radar processor 309 may be configured to provide the determined radar information to a system controller 310 of device/system 301. For example, system controller 310 may include a vehicle controller, e.g., if device/system 301 includes a vehicular device/system, a robot controller, e.g., if device/system 301 includes a robot device/system, or any other type of controller for any other type of device/system 301.

In some demonstrative aspects, the radar information from radar processor 309 may be processed, e.g., by system controller 310 and/or any other element of system 301, for example, in combination with information from one or more other of information sources, for example, LiDAR information from a LiDAR processor, vision information from a vision-based processor, or the like.

In some demonstrative aspects, an environmental model of an environment of system 301 may be determined, e.g., by system controller 310 and/or any other element of system 301, for example, based on the radar information from radar processor 309, and/or the information from one or more other of information sources.

In some demonstrative aspects, a driving policy system, e.g., which may be implemented by system controller 310 and/or any other element of system 301, may process the environmental model, for example, to decide on one or more actions, which may be taken.

In some demonstrative aspects, system controller 310 may be configured to control one or more controlled system components 311 of the system 301, e.g. a motor, a brake, steering, and the like, e.g. by one or more corresponding actuators, for example, based on the one or more action decisions.

In some demonstrative aspects, radar device 300 may include a storage 312 or a memory 313, e.g., to store information processed by radar 300, for example, digital radar reception data values being processed by the radar processor 309, radar information generated by radar processor 309, and/or any other data to be processed by radar processor 309.

In some demonstrative aspects, device/system 301 may include, for example, an application processor 314 and/or a communication processor 315, for example, to at least partially implement one or more functionalities of system controller 310 and/or to perform communication between system controller 310, radar device 300, the controlled system components 311, and/or one or more additional elements of device/system 301.

In some demonstrative aspects, radar device 300 may be configured to generate and transmit the radio transmit signal in a form, which may support determination of range, speed, and/or direction, e.g., as described below.

For example, a radio transmit signal of a radar may be configured to include a plurality of pulses. For example, a pulse transmission may include the transmission of short high-power bursts in combination with times during which the radar device listens for echoes.

For example, in order to more optimally support a highly dynamic situation, e.g., in an automotive scenario, a Continuous Wave (CW) may instead be used as the radio transmit signal. However, a continuous wave, e.g., with constant frequency, may support velocity determination, but may not allow range determination, e.g., due to the lack of a time mark that could allow distance calculation.

In some demonstrative aspects, radio transmit signal 105 (FIG. 1) may be transmitted according to technologies such as, for example, Frequency-Modulated continuous wave (FMCW) radar, Phase-Modulated Continuous Wave (PMCW) radar, Orthogonal Frequency Division Multiplexing (OFDM) radar, and/or any other type of radar technology, which may support determination of range, velocity, and/or direction, e.g., as described below.

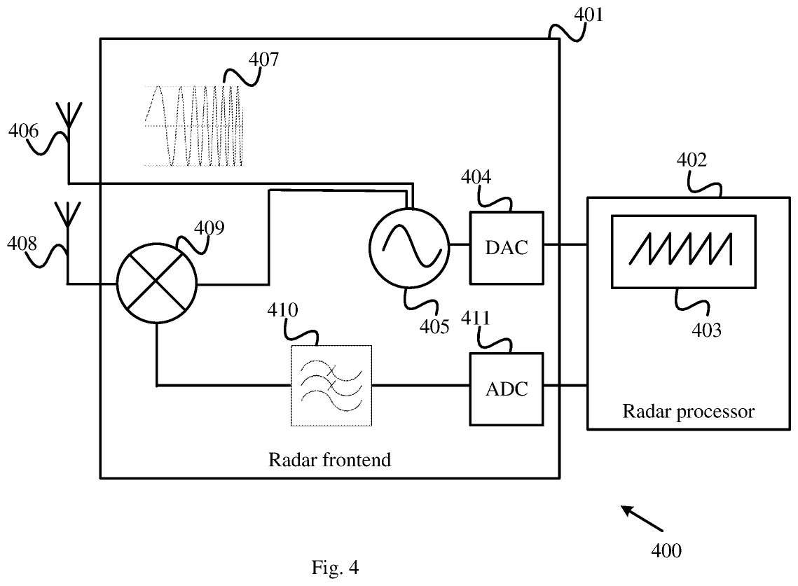

Reference is made to FIG. 4, which schematically illustrates a FMCW radar apparatus, in accordance with some demonstrative aspects.

In some demonstrative aspects, FMCW radar device 400 may include a radar frontend 401, and a radar processor 402. For example, radar frontend 304 (FIG. 3) may include one or more elements of, and/or may perform one or more operations and/or functionalities of, radar frontend 401; and/or radar processor 309 (FIG. 3) may include one or more elements of, and/or may perform one or more operations and/or functionalities of, radar processor 402.

In some demonstrative aspects, FMCW radar device 400 may be configured to communicate radio signals according to an FMCW radar technology, e.g., rather than sending a radio transmit signal with a constant frequency.

In some demonstrative aspects, radio frontend 401 may be configured to ramp up and reset the frequency of the transmit signal, e.g., periodically, for example, according to a saw tooth waveform 403. In other aspects, a triangle waveform, or any other suitable waveform may be used.

In some demonstrative aspects, for example, radar processor 402 may be configured to provide waveform 403 to frontend 401, for example, in digital form, e.g., as a sequence of digital values.

In some demonstrative aspects, radar frontend 401 may include a DAC 404 to convert waveform 403 into analog form, and to supply it to a voltage-controlled oscillator 405. For example, oscillator 405 may be configured to generate an output signal, which may be frequency-modulated in accordance with the waveform 403.

In some demonstrative aspects, oscillator 405 may be configured to generate the output signal including a radio transmit signal, which may be fed to and sent out by one or more transmit antennas 406.

In some demonstrative aspects, the radio transmit signal generated by the oscillator 405 may have the form of a sequence of chirps 407, which may be the result of the modulation of a sinusoid with the saw tooth waveform 403.

In one example, a chirp 407 may correspond to the sinusoid of the oscillator signal frequency-modulated by a “tooth” of the saw tooth waveform 403, e.g., from the minimum frequency to the maximum frequency.

In some demonstrative aspects, a radar device may be configured to utilize radio transmit signals having a form of chirps, e.g., chirps 407, for example, according to a chirp modulation, e.g., as described below.

In other aspects, the radar device may be configured to utilize radio transmit signals configured according to a Phase Modulation (PM), a digital modulation, an OFDM modulation, and/or any other suitable type of modulation.

In some demonstrative aspects, FMCW radar device 400 may include one or more receive antennas 408 to receive a radio receive signal. The radio receive signal may be based on the echo of the radio transmit signal, e.g., in addition to any noise, interference, or the like.

In some demonstrative aspects, radar frontend 401 may include a mixer 409 to mix the radio transmit signal with the radio receive signal into a mixed signal.

In some demonstrative aspects, radar frontend 401 may include a filter, e.g., a Low Pass Filter (LPF) 410, which may be configured to filter the mixed signal from the mixer 409 to provide a filtered signal. For example, radar frontend 401 may include an ADC 411 to convert the filtered signal into digital reception data values, which may be provided to radar processor 402. In another example, the filter 410 may be a digital filter, and the ADC 411 may be arranged between the mixer 409 and the filter 410.

In some demonstrative aspects, radar processor 402 may be configured to process the digital reception data values to provide radar information, for example, including range, speed (velocity/Doppler), and/or direction (AoA) information of one or more objects.

In some demonstrative aspects, radar processor 402 may be configured to perform a first Fast Fourier Transform (FFT) (also referred to as “range FFT”) to extract a delay response, which may be used to extract range information, and/or a second FFT (also referred to as “Doppler FFT”) to extract a Doppler shift response, which may be used to extract velocity information, from the digital reception data values.

In other aspects, any other additional or alternative methods may be utilized to extract range information. In one example, in a digital radar implementation, a correlation with the transmitted signal may be used, e.g., according to a matched filter implementation.

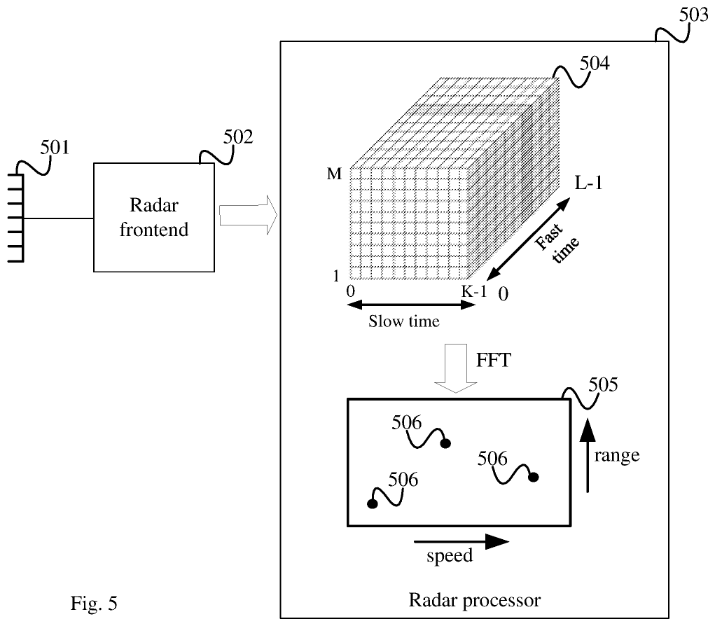

Reference is made to FIG. 5, which schematically illustrates an extraction scheme, which may be implemented to extract range and speed (Doppler) estimations from digital reception radar data values, in accordance with some demonstrative aspects. For example, radar processor 104 (FIG. 1), radar processor 210 (FIG. 2), radar processor 309 (FIG. 3), and/or radar processor 402 (FIG. 4), may be configured to extract range and/or speed (Doppler) estimations from digital reception radar data values according to one or more aspects of the extraction scheme of FIG. 5.

In some demonstrative aspects, as shown in FIG. 5, a radio receive signal, e.g., including echoes of a radio transmit signal, may be received by a receive antenna array 501. The radio receive signal may be processed by a radio radar frontend 502 to generate digital reception data values, e.g., as described above. The radio radar frontend 502 may provide the digital reception data values to a radar processor 503, which may process the digital reception data values to provide radar information, e.g., as described above.

In some demonstrative aspects, the digital reception data values may be represented in the form of a data cube 504. For example, the data cube 504 may include digitized samples of the radio receive signal, which is based on a radio signal transmitted from a transmit antenna and received by M receive antennas. In some demonstrative aspects, for example, with respect to a MIMO implementation, there may be multiple transmit antennas, and the number of samples may be multiplied accordingly.

In some demonstrative aspects, a layer of the data cube 504, for example, a horizontal layer of the data cube 504, may include samples of an antenna, e.g., a respective antenna of the M antennas.

In some demonstrative aspects, data cube 504 may include samples for K chirps. For example, as shown in FIG. 5, the samples of the chirps may be arranged in a so-called “slow time” direction.

In some demonstrative aspects, the data cube 504 may include L samples, e.g., L=512 or any other number of samples, for a chirp, e.g., per each chirp. For example, as shown in FIG. 5, the samples per chirp may be arranged in a so-called “fast time” direction of the data cube 504.

In some demonstrative aspects, processor 504 may be configured to determine the range values, Doppler values, and/or Angle of Arrival (AoA) values, e.g., Azimuth values and/or Elevation values, for example, based on FFT techniques, e.g., as described below.

In other aspects, processor 504 may be configured to determine the range values, Doppler values, and/or Angle of Arrival (AoA) values, e.g., Azimuth values and/or Elevation values, for example, based on Super-Resolution (SR) techniques, and/or any other suitable processing technique.

In some demonstrative aspects, radar processor 503 may be configured to process a plurality of samples, e.g., L samples collected for each chirp and for each antenna, by a first FFT. The first FFT may be performed, for example, for each chirp and each antenna, such that a result of the processing of the data cube 504 by the first FFT may again have three dimensions, and may have the size of the data cube 504 while including values for L range bins, e.g., instead of the values for the L sampling times.

In some demonstrative aspects, radar processor 503 may be configured to process the result of the processing of the data cube 504 by the first FFT, for example, by processing the result according to a second FFT along the chirps, e.g., for each antenna and for each range bin.

For example, the first FFT may be in the “fast time” direction, and the second FFT may be in the “slow time” direction.

In some demonstrative aspects, the result of the second FFT may provide, e.g., when aggregated over the antennas, a range/Doppler (R/D) map 505. The R/D map may have FFT peaks 506, for example, including peaks of FFT output values (in terms of absolute values) for certain range/speed combinations, e.g., for range/Doppler bins. For example, a range/Doppler bin may correspond to a range bin and a Doppler bin. For example, radar processor 503 may consider a peak as potentially corresponding to an object, e.g., of the range and speed corresponding to the peak's range bin and speed bin.

In some demonstrative aspects, the extraction scheme of FIG. 5 may be implemented for an FMCW radar, e.g., FMCW radar 400 (FIG. 4), as described above. In other aspects, the extraction scheme of FIG. 5 may be implemented for any other radar type. In one example, the radar processor 503 may be configured to determine a range/Doppler map 505 from digital reception data values of a PMCW radar, an OFDM radar, or any other radar technologies. For example, in adaptive or cognitive radar, the pulses in a frame, the waveform and/or modulation may be changed over time, e.g., according to the environment.

Referring back to FIG. 3, in some demonstrative aspects, receive antenna arrangement 303 may be implemented using a receive antenna array having a plurality of receive antennas (or receive antenna elements). For example, radar processor 309 may be configured to determine an angle of arrival of the received radio signal, e.g., echo 107 (FIG. 1) and/or echo 215 (FIG. 2). For example, radar processor 309 may be configured to determine a direction of a detected object, e.g., with respect to the device/system 301, for example, based on the angle of arrival of the received radio signal, e.g., as described below.

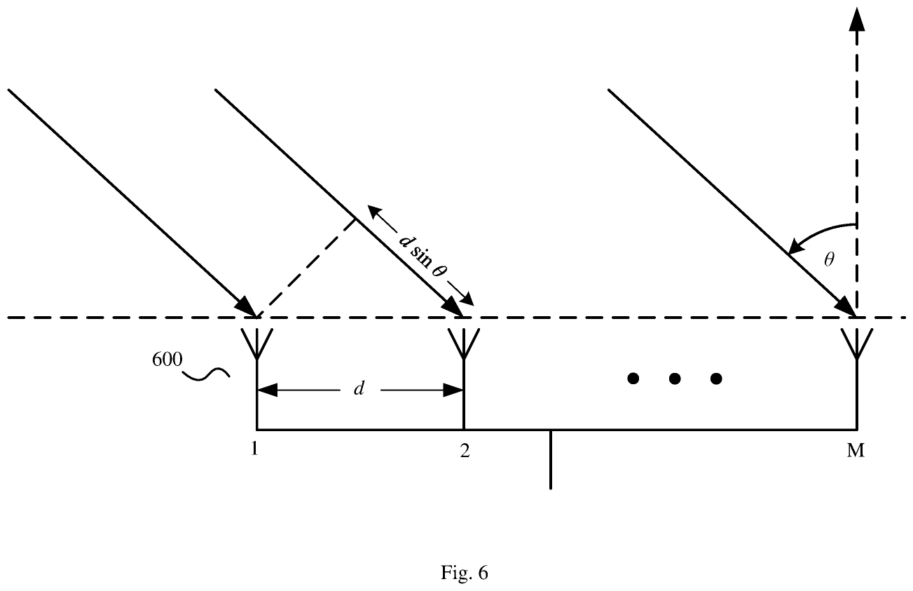

Reference is made to FIG. 6, which schematically illustrates an angle-determination scheme, which may be implemented to determine Angle of Arrival (AoA) information based on an incoming radio signal received by a receive antenna array 600, in accordance with some demonstrative aspects.

FIG. 6 depicts an angle-determination scheme based on received signals at the receive antenna array.

In some demonstrative aspects, for example, in a virtual MIMO array, the angle-determination may also be based on the signals transmitted by the array of Tx antennas.

FIG. 6 depicts a one-dimensional angle-determination scheme. Other multi-dimensional angle determination schemes, e.g., a two-dimensional scheme or a three-dimensional scheme, may be implemented.

In some demonstrative aspects, as shown in FIG. 6, the receive antenna array 600 may include M antennas (numbered, from left to right, 1 to M).

As shown by the arrows in FIG. 6, it is assumed that an echo is coming from an object located at the top left direction. Accordingly, the direction of the echo, e.g., the incoming radio signal, may be towards the bottom right. According to this example, the further to the left a receive antenna is located, the earlier it will receive a certain phase of the incoming radio signal.

For example, a phase difference, denoted Δφ, between two antennas of the receive antenna array 600 may be determined, e.g., as follows:

$$Δφ = \frac{2 π}{λ} \cdot d \cdot sin ( θ )$$

wherein λ denotes a wavelength of the incoming radio signal, d denotes a distance between the two antennas, and θ denotes an angle of arrival of the incoming radio signal, e.g., with respect to a normal direction of the array.

In some demonstrative aspects, radar processor 309 (FIG. 3) may be configured to utilize this relationship between phase and angle of the incoming radio signal, for example, to determine the angle of arrival of echoes, for example by performing an FFT, e.g., a third FFT (“angular FFT”) over the antennas.

In some demonstrative aspects, multiple transmit antennas, e.g., in the form of an antenna array having multiple transmit antennas, may be used, for example, to increase the spatial resolution, e.g., to provide high-resolution radar information. For example, a MIMO radar device may utilize a virtual MIMO radar antenna, which may be formed as a convolution of a plurality of transmit antennas convolved with a plurality of receive antennas.

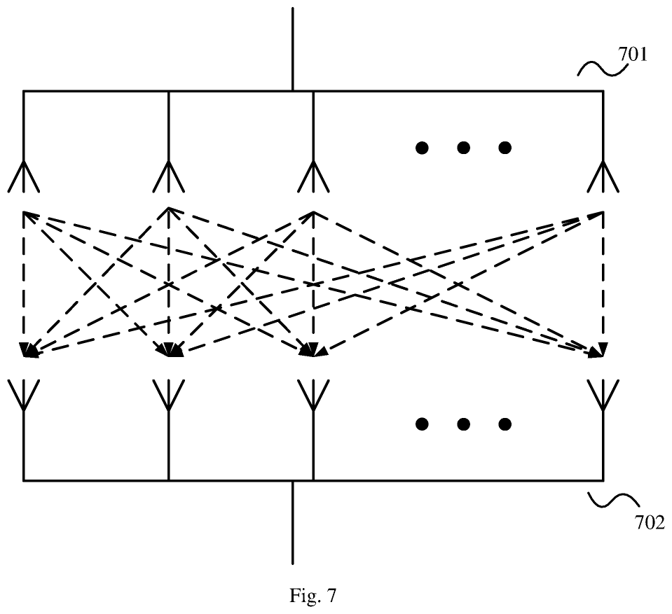

Reference is made to FIG. 7, which schematically illustrates a MIMO radar antenna scheme, which may be implemented based on a combination of Transmit (Tx) and Receive (Rx) antennas, in accordance with some demonstrative aspects.

In some demonstrative aspects, as shown in FIG. 7, a radar MIMO arrangement may include a transmit antenna array 701 and a receive antenna array 702. For example, the one or more transmit antennas 302 (FIG. 3) may be implemented to include transmit antenna array 701, and/or the one or more receive antennas 303 (FIG. 3) may be implemented to include receive antenna array 702.

In some demonstrative aspects, antenna arrays including multiple antennas both for transmitting the radio transmit signals and for receiving echoes of the radio transmit signals, may be utilized to provide a plurality of virtual channels as illustrated by the dashed lines in FIG. 7. For example, a virtual channel may be formed as a convolution, for example, as a Kronecker product, between a transmit antenna and a receive antenna, e.g., representing a virtual steering vector of the MIMO radar.

In some demonstrative aspects, a transmit antenna, e.g., each transmit antenna, may be configured to send out an individual radio transmit signal, e.g., having a phase associated with the respective transmit antenna.

For example, an array of N transmit antennas and M receive antennas may be implemented to provide a virtual MIMO array of size N×M. For example, the virtual MIMO array may be formed according to the Kronecker product operation applied to the Tx and Rx steering vectors.

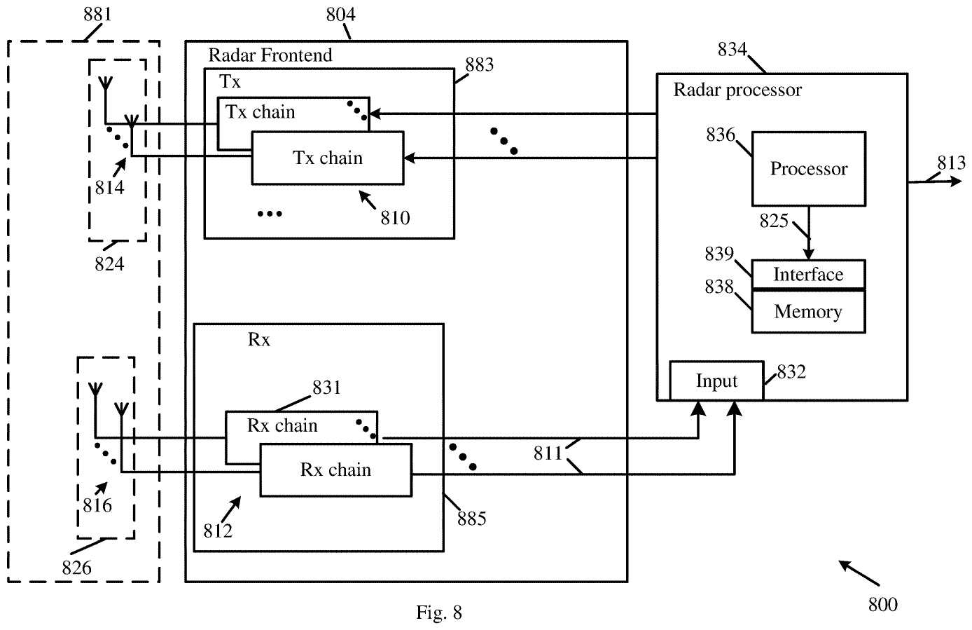

FIG. 8 is a schematic block diagram illustration of elements of a radar device 800, in accordance with some demonstrative aspects. For example, radar device 101 (FIG. 1), radar device 300 (FIG. 3), and/or radar device 400 (FIG. 4), may include one or more elements of radar device 800, and/or may perform one or more operations and/or functionalities of radar device 800.

In some demonstrative aspects, as shown in FIG. 8, radar device 800 may include a radar frontend 804 and a radar processor 834. For example, radar frontend 103 (FIG. 1), radar frontend 211 (FIG. 1), radar frontend 304 (FIG. 3), radar frontend 401 (FIG. 4), and/or radar frontend 502 (FIG. 5), may include one or more elements of radar frontend 804, and/or may perform one or more operations and/or functionalities of radar frontend 804.

In some demonstrative aspects, radar frontend 804 may be implemented as part of a MIMO radar utilizing a MIMO radar antenna 881 including a plurality of Tx antennas 814 configured to transmit a plurality of Tx RF signals (also referred to as “Tx radar signals”); and a plurality of Rx antennas 816 configured to receive a plurality of Rx RF signals (also referred to as “Rx radar signals”), for example, based on the Tx radar signals, e.g., as described below.

In some demonstrative aspects, MIMO antenna array 881, antennas 814, and/or antennas 816 may include or may be part of any type of antennas suitable for transmitting and/or receiving radar signals. For example, MIMO antenna array 881, antennas 814, and/or antennas 816, may be implemented as part of any suitable configuration, structure, and/or arrangement of one or more antenna elements, components, units, assemblies, and/or arrays. For example, MIMO antenna array 881, antennas 814, and/or antennas 816, may be implemented as part of a phased array antenna, a multiple element antenna, a set of switched beam antennas, and/or the like. In some aspects, MIMO antenna array 881, antennas 814, and/or antennas 816, may be implemented to support transmit and receive functionalities using separate transmit and receive antenna elements. In some aspects, MIMO antenna array 881, antennas 814, and/or antennas 816, may be implemented to support transmit and receive functionalities using common and/or integrated transmit/receive elements.

In some demonstrative aspects, MIMO radar antenna 881 may include a rectangular MIMO antenna array, and/or curved array, e.g., shaped to fit a vehicle design.

In other aspects, any other form, shape, and/or arrangement of MIMO radar antenna 881 may be implemented.

In some demonstrative aspects, radar frontend 804 may include one or more radios configured to generate and transmit the Tx RF signals via Tx antennas 814;

and/or to process the Rx RF signals received via Rx antennas 816, e.g., as described below.

In some demonstrative aspects, radar frontend 804 may include at least one transmitter (Tx) 883 including circuitry and/or logic configured to generate and/or transmit the Tx radar signals via Tx antennas 814.

In some demonstrative aspects, radar frontend 804 may include at least one receiver (Rx) 885 including circuitry and/or logic to receive and/or process the Rx radar signals received via Rx antennas 816, for example, based on the Tx radar signals.

In some demonstrative aspects, transmitter 883, and/or receiver 885 may include circuitry; logic; Radio Frequency (RF) elements, circuitry and/or logic; baseband elements, circuitry and/or logic; modulation elements, circuitry and/or logic; demodulation elements, circuitry and/or logic; amplifiers; analog to digital and/or digital to analog converters; filters; and/or the like.

In some demonstrative aspects, transmitter 883 may include a plurality of Tx chains 810 configured to generate and transmit the Tx RF signals via Tx antennas 814, e.g., respectively; and/or receiver 885 may include a plurality of Rx chains 812 configured to receive and process the Rx RF signals received via the Rx antennas 816, e.g., respectively.

In some demonstrative aspects, radar processor 834 may be configured to generate radar information 813, for example, based on the radar signals communicated by MIMO radar antenna 881, e.g., as described below. For example, radar processor 104 (FIG. 1), radar processor 210 (FIG. 2), radar processor 309 (FIG. 3), radar processor 402 (FIG. 4), and/or radar processor 503 (FIG. 5), may include one or more elements of radar processor 834, and/or may perform one or more operations and/or functionalities of radar processor 834.

In some demonstrative aspects, radar processor 834 may be configured to generate radar information 813, for example, based on radar Rx data 811 received from the plurality of Rx chains 812. For example, radar Rx data 811 may be based on the radar Rx signals received via the Rx antennas 816.

In some demonstrative aspects, radar processor 834 may include an input 832 to receive radar input data, e.g., including the radar Rx data 811 from the plurality of Rx chains 812.

In some demonstrative aspects, input 832 may include any suitable input interface, input unit, input module, input component, input circuitry, memory interface, memory access unit, memory reader, digital memory unit, bus interface, processor interface, or the like, which may be capable of receiving the radar input data from a memory, a processor, and/or any other suitable component to provide the radar input data.

In some demonstrative aspects, radar processor 834 may include, or may be implemented, partially or entirely, by circuitry and/or logic, e.g., one or more processors including circuitry and/or logic, memory circuitry and/or logic. Additionally or alternatively, one or more functionalities of radar processor 834 may be implemented by logic, which may be executed by a machine and/or one or more processors, e.g., as described below.

In some demonstrative aspects, radar processor 834 may include at least one processor 836, which may be configured, for example, to process the radar Rx data 811, and/or to perform one or more operations, methods, and/or algorithms.

In some demonstrative aspects, radar processor 834 may include at least one memory 838, e.g., coupled to the processor 836. For example, memory 838 may be configured to store data processed by radar processor 834. For example, memory 838 may store, e.g., at least temporarily, at least some of the information processed by the processor 836, and/or logic to be utilized by the processor 836.

In some demonstrative aspects, processor 836 may interface with memory 838, for example, via a memory interface 839.

In some demonstrative aspects, processor 836 may be configured to access memory 838, e.g., to write data to memory 838 and/or to read data from memory 838, for example, via memory interface 839.

In some demonstrative aspects, memory 838 may be configured to store at least part of the radar data, e.g., some of the radar Rx data or all of the radar Rx data, for example, for processing by processor 836, e.g., as described below.

In some demonstrative aspects, memory 838 may be configured to store processed data, which may be generated by processor 836, for example, during the process of generating the radar information 813, e.g., as described below.

In some demonstrative aspects, memory 838 may be configured to store range information and/or Doppler information, which may be generated by processor 836, for example, based on the radar Rx data. In one example, the range information and/or Doppler information may be determined based on a Cross-Correlation (XCORR) operation, which may be applied to the radar Rx data. Any other additional or alternative operation, algorithm, and/or procedure may be utilized to generate the range information and/or Doppler information.

In some demonstrative aspects, memory 838 may be configured to store AoA information, which may be generated by processor 836, for example, based on the radar Rx data, the range information and/or Doppler information. In one example, the AoA information may be determined based on an AoA estimation algorithm. Any other additional or alternative operation, algorithm, and/or procedure may be utilized to generate the AoA information.

In some demonstrative aspects, radar processor 834 may be configured to generate the radar information 813 including one or more of range information, Doppler information, and/or AoA information.

In some demonstrative aspects, the radar information 813 may include Point Cloud 1 (PC1) information, for example, including raw point cloud estimations, e.g., Range, Radial Velocity, Azimuth, and/or Elevation.

In some demonstrative aspects, the radar information 813 may include Point Cloud 2 (PC2) information, which may be generated, for example, based on the PC1 information. For example, the PC2 information may include clustering information, tracking information, e.g., tracking of probabilities and/or density functions, bounding box information, classification information, orientation information, and the like.

In some demonstrative aspects, the radar information 813 may include target tracking information corresponding to a plurality of targets in an environment of the radar device 800, e.g., as described below.

In some demonstrative aspects, radar processor 834 may be configured to generate the radar information 813 in the form of four Dimensional (4D) image information, e.g., a cube, which may represent 4D information corresponding to one or more detected targets.

In some demonstrative aspects, the 4D image information may include, for example, range values, e.g., based on the range information, velocity values, e.g., based on the Doppler information, azimuth values, e.g., based on azimuth AoA information, elevation values, e.g., based on elevation AoA information, and/or any other values.

In some demonstrative aspects, radar processor 834 may be configured to generate the radar information 813 in any other form, and/or including any other additional or alternative information.

In some demonstrative aspects, radar processor 834 may be configured to process the signals communicated via MIMO radar antenna 881 as signals of a virtual MIMO array formed by a convolution of the plurality of Rx antennas 816 and the plurality of Tx antennas 814.

In some demonstrative aspects, radar frontend 804 and/or radar processor 834 may be configured to utilize MIMO techniques, for example, to support a reduced physical array aperture, e.g., an array size, and/or utilizing a reduced number of antenna elements. For example, radar frontend 804 and/or radar processor 834 may be configured to transmit orthogonal signals via one or more Tx arrays 824 including a plurality of N elements, e.g., Tx antennas 814, and processing received signals via one or more Rx arrays 826 including a plurality of M elements, e.g., Rx antennas 816.

In some demonstrative aspects, utilizing the MIMO technique of transmission of the orthogonal signals from the Tx arrays 824 with N elements and processing the received signals in the Rx arrays 826 with M elements may be equivalent, e.g., under a far field approximation, to a radar utilizing transmission from one antenna and reception with N*M antennas. For example, radar frontend 804 and/or radar processor 834 may be configured to utilize MIMO antenna array 881 as a virtual array having an equivalent array size of N*M, which may define locations of virtual elements, for example, as a convolution of locations of physical elements, e.g., the antennas 814 and/or 816.

In some demonstrative aspects, a radar system may include a plurality of radar devices 800. For example, vehicle 100 (FIG. 1) may include a plurality of radar devices 800, e.g., as described below.

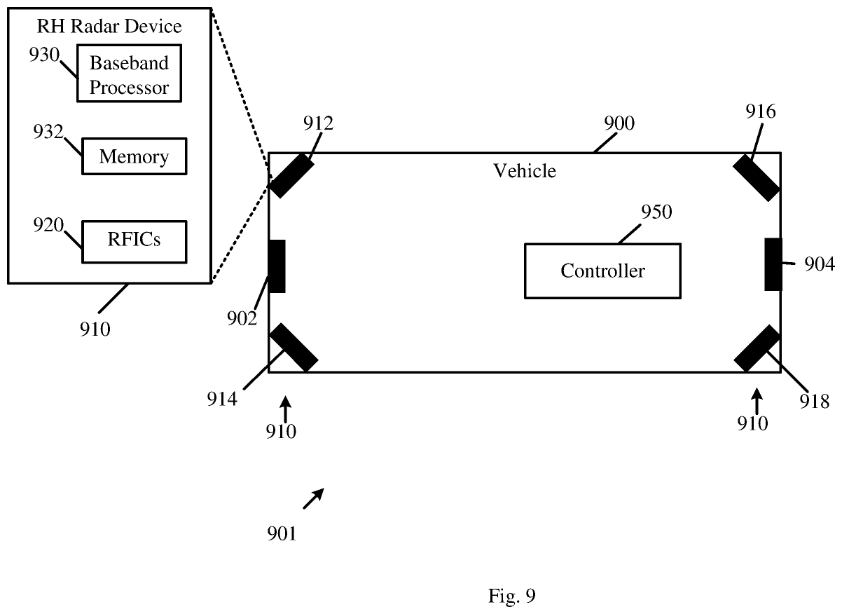

Reference is made to FIG. 9, which schematically illustrates a radar system 901 including a plurality of Radio Head (RH) radar devices (also referred to as RHs) 910 implemented in a vehicle 900, in accordance with some demonstrative aspects.

In some demonstrative aspects, as shown in FIG. 9, the plurality of RH radar devices 910 may be located, for example, at a plurality of positions around vehicle 900, for example, to provide radar sensing at a large field of view around vehicle 900, e.g., as described below.

In some demonstrative aspects, as shown in FIG. 9, the plurality of RH radar devices 910 may include, for example, six RH radar devices 910, e.g., as described below.

In some demonstrative aspects, the plurality of RH radar devices 910 may be located, for example, at a plurality of positions around vehicle 900, which may be configured to support 360-degrees radar sensing, e.g., a field of view of 360 degrees surrounding the vehicle 900, e.g., as described below.

In one example, the 360-degrees radar sensing may allow to provide a radar-based view of substantially all surroundings around vehicle 900, e.g., as described below.

In other aspects, the plurality of RH radar devices 910 may include any other number of RH radar devices 910, e.g., less than six radar devices or more than six radar devices.

In other aspects, the plurality of RH radar devices 910 may be positioned at any other locations and/or according to any other arrangement, which may support radar sensing at any other field of view around vehicle 900, e.g., 360-degrees radar sensing or radar sensing of any other field of view.

In some demonstrative aspects, as shown in FIG. 9, vehicle 900 may include a first RH radar device 902, e.g., a front RH, at a front-side of vehicle 900.

In some demonstrative aspects, as shown in FIG. 9, vehicle 900 may include a second RH radar device 904, e.g., a back RH, at a back-side of vehicle 900.

In some demonstrative aspects, as shown in FIG. 9, vehicle 900 may include one or more of RH radar devices at one or more respective corners of vehicle 900. For example, vehicle 900 may include a first corner RH radar device 912 at a first corner of vehicle 900, a second corner RH radar device 914 at a second corner of vehicle 900, a third corner RH radar device 916 at a third corner of vehicle 900, and/or a fourth corner RH radar device 918 at a fourth corner of vehicle 900.

In some demonstrative aspects, vehicle 900 may include one, some, or all, of the plurality of RH radar devices 910 shown in FIG. 9. For example, vehicle 900 may include the front RH radar device 902 and/or back RH radar device 904.

In other aspects, vehicle 900 may include any other additional or alternative radar devices, for example, at any other additional or alternative positions around vehicle 900. In one example, vehicle 900 may include a side radar, e.g., on a side of vehicle 900.

In some demonstrative aspects, as shown in FIG. 9, vehicle 900 may include a radar system controller 950 configured to control one or more, e.g., some or all, of the RH radar devices 910.

In some demonstrative aspects, at least part of the functionality of radar system controller 950 may be implemented by a dedicated controller, e.g., a dedicated system controller or central controller, which may be separate from the RH radar devices 910, and may be configured to control some or all of the RH radar devices 910.

In some demonstrative aspects, at least part of the functionality of radar system controller 950 may be implemented as part of at least one RH radar device 910.

In some demonstrative aspects, at least part of the functionality of radar system controller 950 may be implemented by a radar processor of an RH radar device 910. For example, radar processor 834 (FIG. 8) may include one or more elements of radar system controller 950, and/or may perform one or more operations and/or functionalities of radar system controller 950.

In some demonstrative aspects, at least part of the functionality of radar system controller 950 may be implemented by a system controller of vehicle 900. For example, vehicle controller 108 (FIG. 1) may include one or more elements of radar system controller 950, and/or may perform one or more operations and/or functionalities of radar system controller 950.

In other aspects, one or more functionalities of system controller 950 may be implemented as part of any other element of vehicle 900.

In some demonstrative aspects, as shown in FIG. 9, an RH radar device 910 of the plurality of RH radar devices 910, may include a baseband processor 930 (also referred to as a “Baseband Processing Unit (BPU)”), which may be configured to control communication of radar signals by the RH radar device 910, and/or to process radar signals communicated by the RH radar device 910. For example, baseband processor 930 may include one or more elements of radar processor 834 (FIG. 8), and/or may perform one or more operations and/or functionalities of radar processor 834 (FIG. 8).

In other aspects, an RH radar device 910 of the plurality of RH radar devices 910 may exclude one or more, e.g., some or all, functionalities of baseband processor 930. For example, controller 950 may be configured to perform one or more, e.g., some or all, functionalities of the baseband processor 930 for the RH.

In one example, controller 950 may be configured to perform baseband processing for all RH radar devices 910, and all RH radio devices 910 may be implemented without baseband processors 930.

In another example, controller 950 may be configured to perform baseband processing for one or more first RH radar devices 910, and the one or more first RH radio devices 910 may be implemented without baseband processors 930; and/or one or more second RH radar devices 910 may be implemented with one or more functionalities, e.g., some or all functionalities, of baseband processors 930.

In another example, one or more, e.g., some or all, RH radar devices 910 may be implemented with one or more functionalities, e.g., partial functionalities or full functionalities, of baseband processors 930.

In some demonstrative aspects, baseband processor 930 may include one or more components and/or elements configured for digital processing of radar signals communicated by the RH radar device 910, e.g., as described below.

In some demonstrative aspects, baseband processor 930 may include one or more FFT engines, matrix multiplication engines, DSP processors, and/or any other additional or alternative baseband, e.g., digital, processing components.

In some demonstrative aspects, as shown in FIG. 9, RH radar device 910 may include a memory 932, which may be configured to store data processed by, and/or to be processed by, baseband processor 930. For example, memory 932 may include one or more elements of memory 838 (FIG. 8), and/or may perform one or more operations and/or functionalities of memory 838 (FIG. 8).

In some demonstrative aspects, memory 932 may include an internal memory, and/or an interface to one or more external memories, e.g., an external Double Data Rate (DDR) memory, and/or any other type of memory.

In other aspects, an RH radar device 910 of the plurality of RH radar devices 910 may exclude memory 932. For example, the RH radar device 910 may be configured to provide radar data to controller 950, e.g., in the form of raw radar data.

In some demonstrative aspects, as shown in FIG. 9, RH radar device 910 may include one or more RF units, e.g., in the form of one or more RF Integrated Chips (RFICs) 920, which may be configured to communicate radar signals, e.g., as described below.

For example, an RFIC 920 may include one or more elements of front-end 804 (FIG. 8), and/or may perform one or more operations and/or functionalities of front-end 804 (FIG. 8).

In some demonstrative aspects, the plurality of RFICs 920 may be operable to form a radar antenna array including one or more Tx antenna arrays and one or more Rx antenna arrays.

For example, the plurality of RFICs 920 may be operable to form MIMO radar antenna 881 (FIG. 8) including Tx arrays 824 (FIG. 8), and/or Rx arrays 826 (FIG. 8).

In some demonstrative aspects, a radar device, e.g., as described above with reference to FIGS. 1-9, may be configured to implement a Printed Circuit Board (PCB) to Wave-Guide (WG) transition mechanism, e.g., as described below.

In some demonstrative aspects, in some use cases and/or scenarios, realization of radar antennas using a waveguide (WG) technology may increase a maximum detection range of a radar, e.g., by tens of percent, for example, compared to printed antennas.

In some demonstrative aspects, there may be a need to provide a technical solution to support a highly efficient PCB-to-waveguide transition, e.g., an RF transition, between an Integrated Circuit (IC), e.g., a packaged chip, which may be located on the PCB, and a WG structure, e.g., a 3D WG structure.

In some demonstrative aspects, a PCB-to-waveguide transition between a PCB and a WG may be configured to connect between chip transceivers and WG-based traces and antennas.

In some demonstrative aspects, implementing WG-based traces and antennas, e.g., using the WG technology, may significantly improve a radar link budget, and/or may increase a maximum detection range of a radar, e.g., by tens of percent, for example, compared to printed traces and printed antennas.

In one example, the WG-based traces and antennas may be filled with air and, hence, may be less lossy, for example, compared to the printed traces and printed antennas, which may be composed of lossy dielectric materials.

In another example, a printed-antenna-based structure including printed antennas may be composed of long PCB traces and PCB antennas, which may contain lossy dielectrics. In contrast, a WG-based architecture including WG-based traces and antennas may utilize short PCB traces with negligible losses, and WG-based traces and antennas, which may be filled with air and, hence, may be less lossy.

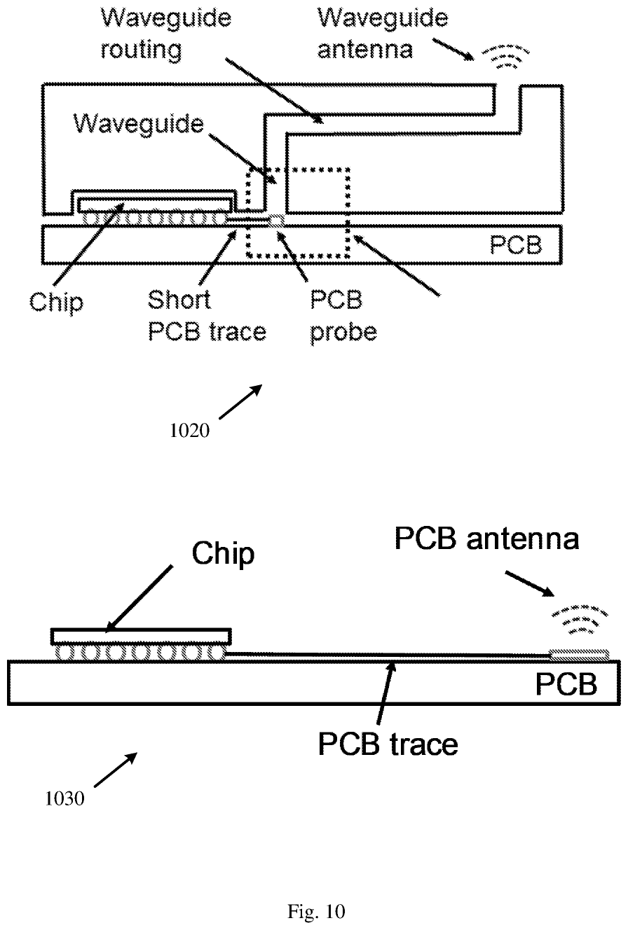

Reference is made to FIG. 10, which schematically illustrates a WG-based structure 1020 and a printed-antenna-based structure 1030 to illustrate one or more technical aspects, which may be addressed in accordance with some demonstrative aspects.

As shown in FIG. 10, printed-antenna-based structure 1030 may include an IC (chip), a PCB trace, and a PCB-based antenna (PCB antenna).

As shown in FIG. 10, WG-based structure 1020 may include an IC (chip), which may be connected to a WG, for example, via a PCB trace and a PCB-to-WG transition.

For example, as shown in FIG. 10, the PCB-to-WG transition may include a PCB probe, which may be configured to excite the WG. For example, the PCB trace may connect between the IC and the PCB probe.

For example, as shown in FIG. 10, the WG may include a WG antenna, and a WG routing to route signals between the WG antenna and the PCB probe.

As shown in FIG. 10, the PCB trace of WG-based structure 1020 may include a short PCB trace, for example, compared to the longer PCB trace of printed-antenna-based system 1030.

In some demonstrative aspects, for example, in some use cases and/or implementations, WG-based structures may utilize multiple WG-based antenna elements, which may be connected to a PCB via a plurality of waveguides. For example, the WG-based structures may utilize a plurality of PCB traces to connect between the plurality of waveguides and one or more chip transceivers.

In some demonstrative aspects, it may be advantageous to utilize PCB-to-WG transitions (PCB to WG-narrow-side transitions), which may be configured to enter a narrow-side of the WGs, for example, rather than PCB-to-WG transitions (PCB to WG-wide-side transitions), which may be configured to enter a wide-side of the WGs, e.g., as described below.

In some demonstrative aspects, the PCB to WG-narrow-side transitions may be implemented to provide a technical solution to reduce the PCB trace area, for example, by feeding a rectangular shape of the WG from its narrow side, e.g., as described below.

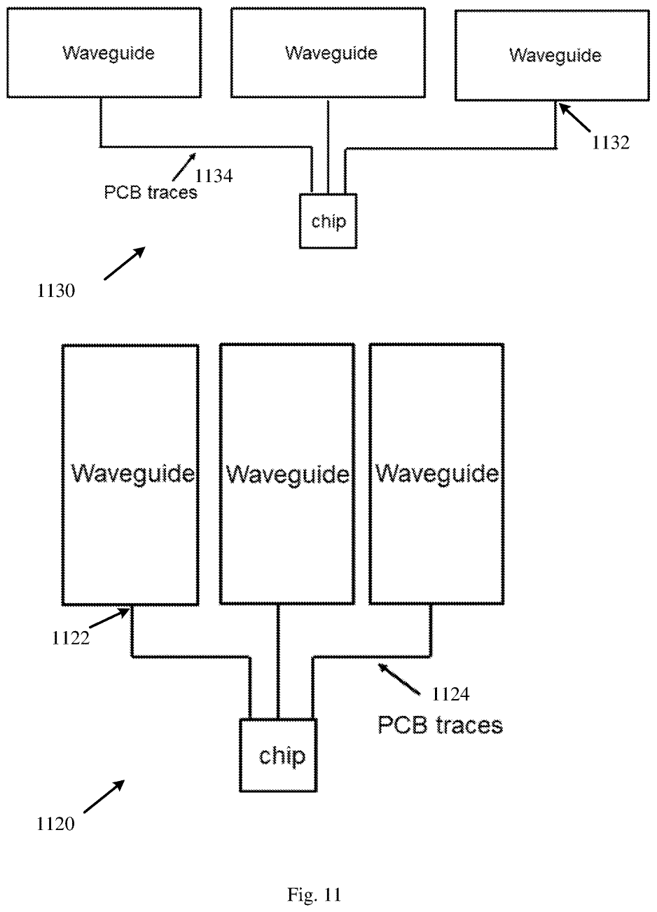

Reference is made to FIG. 11, which schematically illustrates a WG-based structure 1120 including PCB to WG-narrow-side transitions 1122, and a WG-based structure 1130 including PCB to WG-wide-side transitions 1132, to illustrate one or more technical aspects, which may be addressed in accordance with some demonstrative aspects.

For example, as shown in FIG. 11, the implementation of the PCB to WG-narrow-side transitions 1122 may provide a technical solution to support a side-by-side arrangement of the waveguides, for example, along the wide sides of the WGs.

For example, as shown in FIG. 11, the implementation of the PCB to WG-narrow-side transitions 1122 may provide a technical solution to support utilizing relatively short PCB traces 1124 to connect between a chip and the narrow sides of the plurality of WGs.

For example, as shown in FIG. 11, in contrast to the implementation of the PCB to WG-narrow-side transitions 1122, the implementation of the PCB to WG-wide-side transitions 1132 may require a side-by-side arrangement of the waveguides, for example, along the narrow sides of the WGs.

For example, as shown in FIG. 11, the implementation of the PCB to WG-wide-side transitions 1132 may require the use of relatively long PCB traces 1134 to connect between a chip and the wide sides of the plurality of WGs.

For example, as shown in FIG. 11, WG-based structure 1120 may have a reduced trace area of the PCB traces 1124, for example, compared to a trace area of the PCB traces 1134.

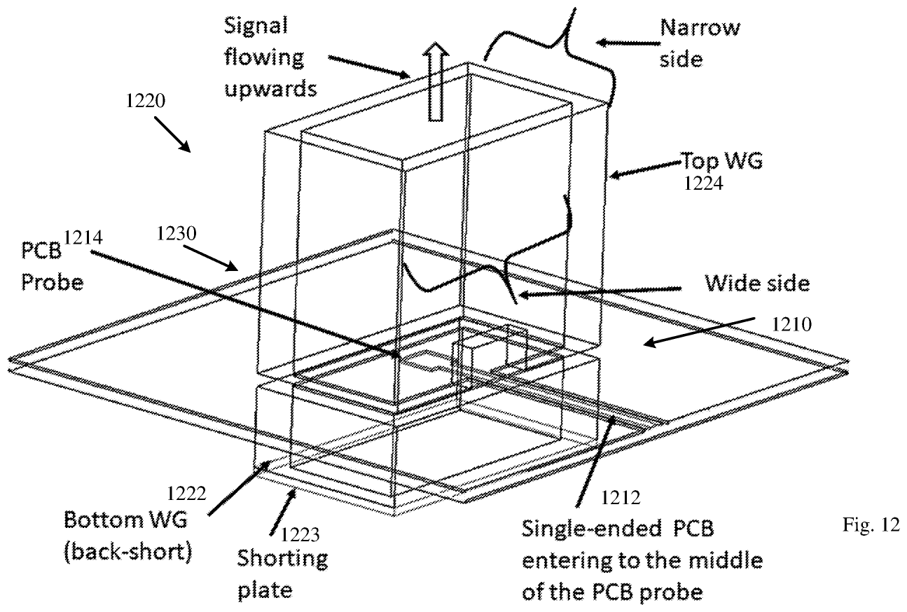

Reference is made to FIG. 12, which schematically illustrates a PCB to WG-wide-side transition 1210 to illustrate one or more technical aspects, which may be addressed in accordance with some demonstrative aspects.

For example, as shown in FIG. 12, a single-ended PCB trace 1212, e.g., a micro-strip, may feed a WG area of a WG 1220, for example, by entering from a wide side of a rectangular WG shape of the WG 1220.

For example, as shown in FIG. 12, a probe 1214 may be printed at an end of the trace 1212.

For example, as shown in FIG. 12, the single-ended PCB trace 1212 may be connected to a middle of the PCB probe 1214, for example, in order to achieve matching between impedances of the printed trace 1212 and the WG 1220.

For example, as shown in FIG. 12, the WG 1220 may be assembled and/or connected from both sides of a PCB 1230.

For example, as shown in FIG. 12, WG 1220 may include a double-sided assembly, e.g., including a top WG 1224 and a bottom WG 1222 (also referred to as a “back-short”).

For example, as shown in FIG. 12, the bottom WG 1222 may be short-circuited, e.g., to a shorting plate 1223.

For example, a length of the back-short 1222 may be about a quarter of a wavelength, e.g., about 1 millimeter (mm) in case of an 80 GHz radar, for example, to direct RF signals upwards, and to create a constructive interference between an energy reflected from the capped back-short 1222 and the energy that flows into the top WG 1224.

For example, as shown in FIG. 12, the double-sided assembly of WG 1220 may add complexity to an assembly process.

For example, as shown in FIG. 12, entering the WG 1220 from the wide-side of WG 1220 may consume a large transition volume, and therefore may be less attractive, for example, in cases where multiple transitions from a chip to radar array elements are required. For example, entering the WG 1220 from the wide-side of WG 1220 may result in longer PCB traces, for example, when multiple waveguides are used, e.g., as described above with reference to FIG. 11.

In some demonstrative aspects, a PCB to WG-narrow-side transition may be implemented to provide a technical solution to address one or more of the technical issues of the PCB to WG-wide-side transition, e.g., as described below.

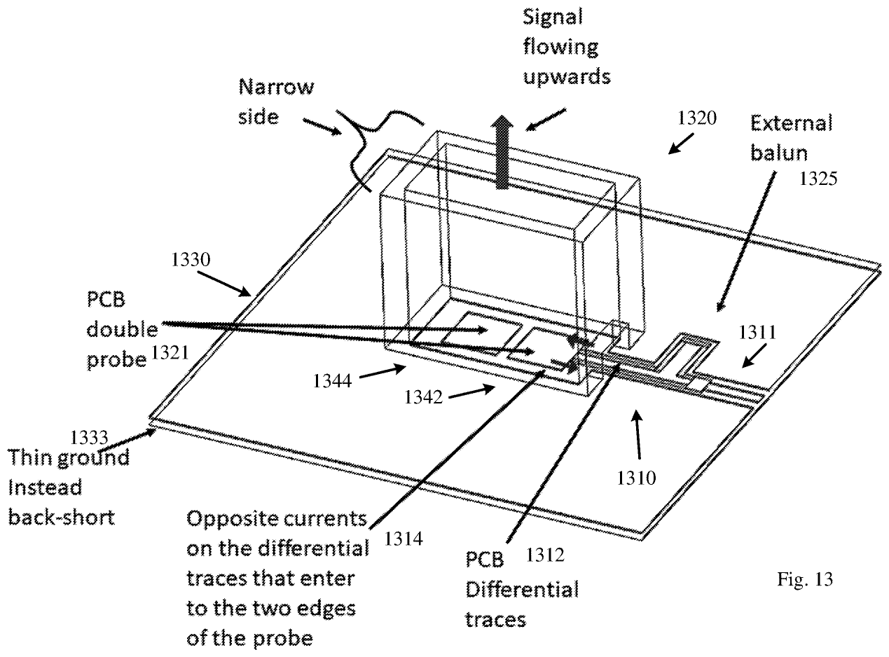

FIG. 13 is a schematic illustration of a PCB to WG-narrow-side transition 1310 to illustrate one or more technical aspects, which may be addressed in accordance with some demonstrative aspects.

For example, as shown in FIG. 13, PCB to WG-narrow-side transition 1310 may be simpler and smaller, for example, compared to the PCB to WG-wide-side transition 1210 (FIG. 12).

For example, a WG-based structure, e.g., WG-based structure 1120 (FIG. 11) utilizing the PCB to WG-narrow-side transition 1310, may provide a technical solution to support shorter PCB traces, for example, compared to a WG-based structure, e.g., WG-based structure 1130 (FIG. 11) utilizing the PCB to WG-wide-side transition, e.g., as described above with reference to FIG. 11.

For example, as shown in FIG. 13, PCB to WG-narrow-side transition 1310 may include a double-probe structure 1321, e.g., including a first PCB probe 1342 and a second PCB probe 1344, which may be configured for example, to apply a better impedance matching between a PCB 1330 and a WG 1320.

For example, as shown in FIG. 13, a ground layer 1333 of PCB 1330 may be located close to the WG 1320, e.g., at a distance of about 0.1 mm in case of an 80 GHz radar, and may serve as a thin replacement for the back-short 1222 (FIG. 12).

For example, the ground layer 1333 may be used instead of the back-short 1222 (FIG. 12), for example, to reduce dimensions of the WG 1320.

For example, as shown in FIG. 13, PCB to WG-narrow-side transition 1310 may be configured to enter the WG 1320 from a narrow-side of the WG 1320.

For example, the entrance from the narrow side of the WG 1320 may be particularly advantageous for placement of multiple transitions side by side, and connecting between a plurality of densely spaced chip transceivers and a plurality of antenna elements of an antenna array, e.g., as described above with reference to FIG. 11.

However, an implementation utilizing the PCB to WG-narrow-side transition 1310, e.g., without a back-short, may suffer from reduced bandwidth, for example, compared to a bandwidth supported by the PCB to WG-wide-side transition 1210 (FIG. 12).

For example, it may be challenging to achieve coverage of an entire 76-81 GHz automotive radar frequency with an implementation utilizing PCB to WG-narrow-side transition 1310.

For example, as shown in FIG. 13, to compensate for some of the bandwidth degradation, the WG 1320 may be fed using differential traces 1312, for example, instead of a single ended PCB trace.

For example, the differential traces 1312 may be configured such that forward and backward currents 1314 that flow on the differential traces 1312 may enter via two edges of the PCB probe 1342.

Unfortunately, the use of the differential traces 1312 may be on the expense of reducing a routing flexibility, e.g., especially when trace twists and turns are implemented.

For example, as shown in FIG. 13, a balancing unit (balun) 1325, e.g., an external balun, which may be bulky and relatively lossy, may be added, for example, to match between the differential traces 1312 and a single-ended chip interface 1311.

For example, the balun 1325 may be configured as a delay-and-sum section, which includes two arms with 180 phase difference, for example, such that the opposite currents flowing on the two differential traces 1312 may arrive to the single-ended trace 1311, e.g., at the same phase and direction.

For example, as shown in FIG. 13, implementation of the PCB to WG-narrow-side transition 1310 may obviate a need for a back-short, and may use shorter PCB traces. However, the PCB to WG-narrow-side transition 1310 may require implementation of the bulky differential lines 1312, the lossy external balun 1325, and may suffer from a limited, relatively narrow, bandwidth.

In some demonstrative aspects, a radar device, e.g., as described above with reference to FIGS. 1-9, may be configured to implement a wideband and compact PCB to WG transition with an “integrated balun”, e.g., as described below.

In some demonstrative aspects, a radar device, e.g., as described above with reference to FIGS. 1-9, may be configured to implement a PCB to WG transition, which may be configured to make use of a unique “integrated balun”, which may allow feeding a rectangular WG from its narrow side, for example, while operating at the entire 76-81 GHz automotive band, e.g., as described below.

In some demonstrative aspects, a radar device, e.g., as described above with reference to FIGS. 1-9, may be configured to implement a PCB to WG transition, which may be configured to make use of a unique “integrated balun”, which may provide a technical solution to support a small form factor, structural simplicity, and/or a wide operating bandwidth, for example, compared to the PCB to WG-narrow-side transition 1310 (FIG. 13), e.g., as described below.

In some demonstrative aspects, a radar device, e.g., as described above with reference to FIGS. 1-9, may be configured to implement a PCB to WG transition, which may be configured to implement a unique “internal balun” structure, which may be implemented inside a WG area of a WG. This mechanism may provide a technical solution to support wide bandwidth, for example, even without increasing the loss and/or area of the transition, e.g., as described below.

In some demonstrative aspects, the PCB to WG transition may be configured to provide a technical solution to support high performance WG-based radars, for example, operating at an entire 76-81 GHz automotive frequency band, e.g., as described below.

In some demonstrative aspects, the PCB to WG transition may be configured to provide a technical solution to support the high performance WG-based radars, for example, while offering small form factor, low loss, and/or structural simplicity, which may allow saving cost and/or reducing the radar size, e.g., as described below.

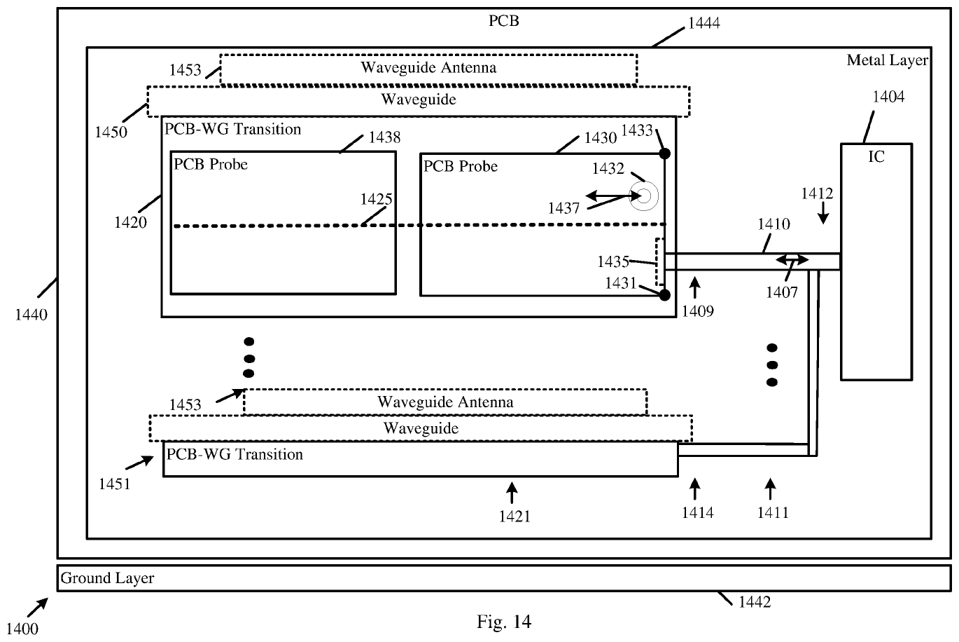

Reference is made to FIG. 14, which schematically illustrates a system 1400, in accordance with some demonstrative embodiments.

In some demonstrative aspects, as shown in FIG. 14, system 1400 may include a PCB 1440, and an Integrated Circuit (IC) 1404, which may be connected to the PCB 1440, e.g., as described below.

In some demonstrative aspects, as shown in FIG. 14, system 1400 may include one or more waveguides 1451, and one or more waveguide antennas 1533, for example, at ends of the one or more waveguides 1451, e.g., as described below.

In some demonstrative aspects, as shown in FIG. 14, PCB 1440 may include one or more single-ended PCB traces 1411, which may be configured to route single-ended RF signals 1407, for example, between the integrated circuit 1404 and the one or more waveguides 1451, e.g., as described below.

In some demonstrative aspects, as shown in FIG. 14, first ends 1412 of the one or more single-ended PCB traces 1411 may be coupled to the integrated circuit 1404, e.g., as described below.

In some demonstrative aspects, as shown in FIG. 14, the integrated circuit 1404 may be connected to the one or more single-ended PCB traces 1411, for example, via the first ends 1412 of the one or more single-ended PCB traces 1411, e.g., as described below.

In some demonstrative aspects, as shown in FIG. 14, PCB 1440 may include one or more PCB-to-waveguide transitions 1421, which may be configured to couple second ends 1414 of the one or more single-ended PCB traces 1411 to the one or more waveguides 1451, e.g., as described below.

In some demonstrative aspects, as shown in FIG. 14, a PCB-to-waveguide transition 1420 of the one or more PCB-to-waveguide transitions 1421 may include a PCB probe 1430, e.g., as described below.

In some demonstrative aspects, the PCB probe 1430 may include a probe patch, e.g., as described below.

In some demonstrative aspects, as shown in FIG. 14, the PCB probe 1430 may include a rectangular probe patch, e.g., as described below.

In other aspects, the PCB probe 1430 may include any other type of probe having any other suitable shape.

In some demonstrative aspects, as shown in FIG. 14, the PCB probe 1430 may be connected to a second end 1409 of a single-ended PCB trace 1410 of the one or more single-ended PCB traces 1411, e.g., as described below.

In some demonstrative aspects, as shown in FIG. 14, the PCB probe 1430 and the PCB probe 1438 may be configured to couple RF energy of the single-ended RF signals 1407 between the single-ended PCB trace 1410 and a waveguide 1450 of the one or more waveguides 1451, e.g., as described below.

In some demonstrative aspects, as shown in FIG. 14, the PCB-to-waveguide transition 1420 may include a via 1432, e.g., as described below.

In some demonstrative aspects, via 1432 may be configured to electrically connect the PCB probe 1430 to a ground layer 1442 of the PCB 1440, e.g., as described below.

In some demonstrative aspects, as shown in FIG. 14, the PCB-to-waveguide transition 1420 may be configured as a PCB-to-narrow-waveguide-side transition, which may be configured to couple the single-ended PCB trace 1410 to the waveguide 1450, for example, via a narrow side of a rectangular shape of the waveguide 1450, e.g., as described below.

In some demonstrative aspects, as shown in FIG. 14, the one or more single-ended PCB traces 1411 may include a plurality of single-ended PCB traces 1411 to route the single-ended RF signals 1407 between the integrated circuit 1404 and a plurality of waveguides 1450, e.g., as described below.

In some demonstrative aspects, as shown in FIG. 14, the plurality of single-ended PCB traces 1411 may be arranged on the PCB 1440, for example, according to a trace arrangement, which may be configured, for example, to couple second ends of the plurality of single-ended PCB traces 1411 to narrow sides of the plurality of waveguides 1450, e.g., as described below.

In some demonstrative aspects, as shown in FIG. 14, PCB 1440 may include a metal layer 1444 including the one or more single-ended PCB traces 1411 and the PCB probe 1430, e.g., as described below.

In some demonstrative aspects, the PCB-to-waveguide transition 1420 may be configured to couple the single-ended PCB trace 1410 to an end of the waveguide 1450, e.g., as described below.

In some demonstrative aspects, as shown in FIG. 14, the PCB probe 1430 may be connected to a single single-ended PCB trace, e.g., single-ended PCB trace 1410, of the one or more single-ended PCB traces 1411, e.g., as described below.

In some demonstrative aspects, as shown in FIG. 14, the PCB-to-waveguide transition 1420 may include a first PCB probe, e.g., the PCB probe 1430, having a first side connected to the second end 1409 of the single-ended PCB trace 1410, e.g., as described below.

In some demonstrative aspects, as shown in FIG. 14, the via 1432 may be configured to electrically connect the first PCB probe to the ground layer 1442 of the PCB 1440.

In some demonstrative aspects, as shown in FIG. 14, the PCB-to-waveguide transition 1420 may include a second PCB probe 1438, which may be spaced apart from a second side of the first PCB probe opposite to the first side of the first PCB probe, e.g., as described below.

In some demonstrative aspects, as shown in FIG. 14, the second end 1409 of the single-ended PCB trace 1410 may be connected to a trace-probe segment 1435 of a side of the PCB probe 1430, e.g., as described below.

In some demonstrative aspects, the second end 1409 of the single-ended PCB trace 1410 may be substantially perpendicular to the trace-probe segment 1435, e.g., as described below.

In some demonstrative aspects, as shown in FIG. 14, the trace-probe segment 1435 may be on a first side of an axis 1425 through a midpoint of the side of the PCB probe 1430, e.g., as described below.

In some demonstrative aspects, as shown in FIG. 14, the via 1432 may be on a second side of the axis 1425, e.g., as described below.

In some demonstrative aspects, as shown in FIG. 14, the trace-probe segment 1435 may be proximal to a vertex 1431 of the PCB probe 1430, e.g., as described below.

In some demonstrative aspects, as shown in FIG. 14, the trace-probe segment 1435 may be proximal to a first vertex, e.g., vertex 1431, at a first end of the side of the PCB probe 1430, e.g., as described below.

In some demonstrative aspects, as shown in FIG. 14, the via 1432 may be proximal to a second vertex 1433 at a second end of the side of the PCB probe 1430, e.g., as described below.

In some demonstrative aspects, as shown in FIG. 14, the via 1432 may be configured to provide a functionality of an RF balun, for example, to match between differential RF signals of the PCB probe 1430 and the single-ended RF signals 1407 of the single-ended PCB trace 1410, e.g., as described below.

In some demonstrative aspects, as shown in FIG. 14, the via 1432 may be configured to tunnel reverse RF signals 1437 between the PCB probe 1430 and the ground layer 1442, e.g., as described below.

In some demonstrative aspects, the reverse RF signals 1437 may be in a direction opposite to the single-ended RF signals 1407 routed via the single-ended PCB trace 1410, e.g., as described below.

For example, reverse RF signals 1437 may be in a direction to the left, for example, when single-ended RF signals 1407 include signals in a direction to the right, e.g., signals received via the waveguide antenna 1453 and routed via the WG 1450 to the IC 1404.

For example, reverse RF signals 1437 may be in a direction to the right, for example, when single-ended RF signals 1407 include signals in a direction to the left, e.g., signals from the IC routed via the WG 1450 to the waveguide antenna 1453.

In some demonstrative aspects, the one or more single-ended PCB traces 1411 and/or the one or more PCB-to-waveguide transitions 1421 may be configured to route the single-ended RF signals 1407 at a frequency above 70 GHz, e.g., as described below.

In other aspects, the one or more single-ended PCB traces 1411 and/or the one or more PCB-to-waveguide transitions 1421 may be configured to route the single-ended RF signals 1407 in any other frequency.

In some demonstrative aspects, the one or more single ended PCB traces 1411 and/or the one or more PCB-to-waveguide transitions 1421 may be configured to route the single-ended RF signals 1407 in a frequency band of 76-81 GHz, e.g., as described below.

In other aspects, the one or more single ended PCB traces 1411 and/or the one or more PCB-to-waveguide transitions 1421 may be configured to route the single-ended RF signals 1407 in any other suitable frequency bandwidth.

In some demonstrative aspects, the PCB-to-waveguide transition 1420 may be configured, for example, such that a transmission coefficient (S21) of the PCB-to-waveguide transition 1420 may be greater than −1 decibel (dB), for example, for any RF signals having a frequency bandwidth of at least 3 GHZ, e.g., as described below.

In some demonstrative aspects, the PCB-to-waveguide transition 1420 may be configured, for example, such that the S21 of the PCB-to-waveguide transition 1420 may be greater than −1 dB, for example, for any RF signals having a frequency bandwidth of at least 5 GHz, e.g., as described below.

In some demonstrative aspects, the PCB-to-waveguide transition 1420 may be configured, for example, such that the transmission coefficient S21 of the PCB-to-waveguide transition 1420 may be greater than −1 dB, for example, for any RF signals in the frequency band of 76-81 GHz, e.g., as described below.

In other aspects, the PCB-to-waveguide transition 1420 may be configured, for example, such that the transmission coefficient S21 of the PCB-to-waveguide transition 1420 may be configured according to any other antenna matching limitation and/or for any other frequency bandwidth.

In some demonstrative aspects, the PCB-to-waveguide transition 1420 may be configured, for example, such that both a first reflection coefficient (S11) and a second reflection coefficient (S22) of the PCB-to-waveguide transition 1420 may be less than −10 dB, for example, for any RF signals in a frequency band having a frequency bandwidth of at least 3 GHZ, e.g., as described below.

In some demonstrative aspects, the PCB-to-waveguide transition 1420 may be configured, for example, such that both the first reflection coefficient S11 and the second reflection coefficient S22 of the PCB-to-waveguide transition 1420 may be less than −10 dB, for example, for any RF signals in a frequency band having a frequency bandwidth of at least 5 GHz, e.g., as described below.

In some demonstrative aspects, the PCB-to-waveguide transition 1420 may be configured, for example, such that both the first reflection coefficient S11 and the second reflection coefficient S22 of the PCB-to-waveguide transition 1420 may be less than −10 dB, for example, for any RF signals in the frequency band of 76-81 GHZ, e.g., as described below.

In other aspects, the PCB-to-waveguide transition 1420 may be configured, for example, such that the first reflection coefficient S11 and/or the second reflection coefficient S22 of the PCB-to-waveguide transition 1420 may be configured according to any other antenna matching limitation and/or for any other frequency bandwidth.

In some demonstrative aspects, PCB-to-waveguide transition 1420 may be implemented as part of a radar device or system, for example, as part of radar device 800 (FIG. 8), e.g., as described above.

In some demonstrative aspects, PCB-to-waveguide transition 1420 may be implemented as part of any other suitable device and/or system.

For example, in some demonstrative aspects, PCB-to-waveguide transition 1420 may be implemented as part of a device, for example, a mobile device, a computing device, and/or a wireless communication device, for example, to communicate RF wireless communication signals.

For example, in some demonstrative aspects, PCB-to-waveguide transition 1420 may be implemented to communicate the RF wireless communication signals over mmWave frequencies.

In other aspects, PCB-to-waveguide transition 1420 may be implemented by any other wireless communication device, wired communication device, imaging device, and/or any other suitable type of device.

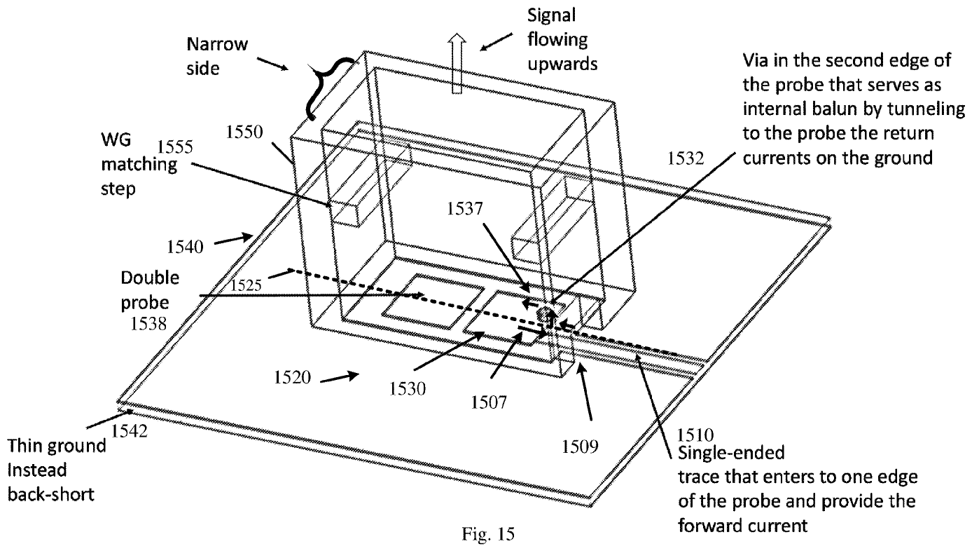

Reference is made to FIG. 15, which schematically illustrates a PCB-to-WG transition 1520, in accordance with some demonstrative aspects.

For example, PCB-to-waveguide transition 1420 (FIG. 14) may include one or more elements of PCB-to-WG transition 1520, and/or may perform one or more operations and/or functionalities of PCB-to-WG transition 1520.

In some demonstrative aspects, as shown in FIG. 15, PCB-to-WG transition 1520 may be configured as a PCB-to-narrow-waveguide-side transition.

In some demonstrative aspects, as shown in FIG. 15, the PCB-to-WG transition 1520 may be configured to couple a single-ended PCB trace 1510 to a waveguide 1550 via a narrow side of a rectangular shape of the waveguide 1550.

In some demonstrative aspects, as shown in FIG. 15, the PCB-to-WG transition 1520 may include a first PCB probe 1530 and a second PCB probe 1538 on a PCB 1540.

In some demonstrative aspects, as shown in FIG. 15, the first PCB probe 1530 and the second PCB probe 1538 may include a rectangular probe patch.

In some demonstrative aspects, as shown in FIG. 15, the PCB probe 1530 may be connected to an end 1509 of the single-ended PCB trace 1510.

In some demonstrative aspects, as shown in FIG. 15, the PCB probe 1530 may have a first side connected to the end 1509 of the single-ended PCB trace 1510.

In some demonstrative aspects, as shown in FIG. 15, the second PCB probe 1538 may be spaced apart from a second side of the PCB probe 1530, which is opposite to the first side of the PCB probe 1530.

In some demonstrative aspects, the PCB probes 1530 and 1538 may be configured to couple RF energy of single-ended RF signals 1507 between the single-ended PCB trace 1510 and the waveguide 1550.

In some demonstrative aspects, as shown in FIG. 15, the PCB-to-WG transition 1520 may include a via 1532.

In some demonstrative aspects, via 1532 may be configured to electrically connect the PCB probe 1530 to a ground layer 1542 of the PCB 1540.

In some demonstrative aspects, the PCB-to-WG transition 1520 may be configured to couple the single-ended PCB trace 1510 to an end of the waveguide 1550.

In some demonstrative aspects, as shown in FIG. 15, the PCB probe 1530 may be connected to a single single-ended PCB trace 1510.

In some demonstrative aspects, as shown in FIG. 15, the end 1509 of the single-ended PCB trace 1510 may be connected to a trace-probe segment of a side of the PCB probe 1530.

In some demonstrative aspects, as shown in FIG. 15, the trace-probe segment may be on a first side of an axis 1525 through a midpoint of the side of the PCB probe 1530.

In some demonstrative aspects, as shown in FIG. 15, the via 1532 may be on a second side of the axis 1525.

In some demonstrative aspects, as shown in FIG. 15, the trace-probe segment 1535 may be proximal to a first vertex at a first end of the side of the PCB probe 1530.

In some demonstrative aspects, as shown in FIG. 15, the via 1532 may be proximal to a second vertex at a second end of the side of the PCB probe 1530.

In some demonstrative aspects, as shown in FIG. 15, the via 1532 may be configured to tunnel reverse RF signals 1537 between the PCB probe 1530 and the ground layer 1542.

In some demonstrative aspects, as shown in FIG. 15, the reverse RF signals 1537 may be in a direction opposite to single-ended RF signals 1507 routed via the single-ended PCB trace 1510.

In some demonstrative aspects, PCB-to-WG transition 1520 may provide a technical solution to support a wide bandwidth of operation, e.g., which may approach a bandwidth of the PCB to WG transition-wide-side 1210 (FIG. 12).

In some demonstrative aspects, as shown in FIG. 15, the wide bandwidth may be achieved, for example, while consuming a small volume. For example, PCB-to-WG transition 1520 may be implemented without a back short, and may support the use of short PCB traces 1510, for example, by entering the narrow side of WG 1550, e.g., as described above with reference to FIG. 11.

In some demonstrative aspects, for example, in contrast to PCB to WG-narrow-side transition 1310 (FIG. 13), PCB-to-WG transition 1520 may have low losses and/or increased routing flexibility, for example, due to the implementation of a single-ended printed trace 1510 while avoiding an external balun and differential lines.

In some demonstrative aspects, as shown in FIG. 15, PCB-to-WG transition 1520 may be configured utilizing a single-ended feeding, e.g., single-ended printed trace 1510, an “integrated balun” via, e.g., via 1532, and/or without a back-short.

In some demonstrative aspects, as shown in FIG. 15, the via 1532 may be connected to a double probe structure, e.g., including probes 1530 and 1538, for example, in order to obviate a need for differential feeding and/or an external balun.

In some demonstrative aspects, the via 1532 may be configured to tunnel backward currents 1537 flowing on the ground layer 1542 to the double probe structure. Accordingly, the via 1532 may be considered to provide a functionality of an integrated balun.

In some demonstrative aspects, this “internal” or integrated balun may be configured to make sure that the double probe structure may be fed from opposite current directions, e.g., as required.

In some demonstrative aspects, as shown in FIG. 15, single-ended printed trace 1510 may be connected in proximity to a first edge of the PCB probe 1530, and may provide the forward currents 1507.

In some demonstrative aspects, as shown in FIG. 15, the via 1532 may be configured to provide the backward currents 1537, for example, in proximity to a second edge of the PCB probe 1530, e.g., opposite to the first edge.

In some demonstrative aspects, as shown in FIG. 15, the via 1532 may be configured to connect between the ground layer 1542 and the PCB probe 1530, for example, to tunnel the backward currents 1537 flowing on the ground.

In some demonstrative aspects, as shown in FIG. 15, the first and second edges of the PCB probe 1530 may continue to be fed with forward and backward currents as required, e.g., similar to PCB to WG-narrow-side transition 1310 (FIG. 13), while avoiding differential lines and/or an external balun.

In some demonstrative aspects, as shown in FIG. 15, the PCB-to-WG transition 1520 may provide a technical solution to support an implementation with low loss and small area, for example, as a balun is implemented by the via 1532 inside a WG area of the WG 1550, while avoiding any external printed sections.

In some demonstrative aspects, as shown in FIG. 15, one or more WG matching steps 1555 may be introduced inside a WG structure of WG 1550, for example, to enhance a transition bandwidth of PCB-to-WG transition 1520.

In some demonstrative aspects, for example, in some cases it may be challenging to ensure perfect galvanic electrical connection between the PCB 1540 and WG sections of WG 1550.

In some demonstrative aspects, a periodic pin structure may be implemented at a bottom of a WG, for example, as even air gaps of less than 100 micrometer (um) may significantly degrade a transition performance at the mmWave range.

In some demonstrative aspects, the pin structure (also referred to as a “bed of nails”) may be configured to act as a filter, which may prevent energy leakage from air gaps between a PCB and a WG, e.g., using a gap technology.

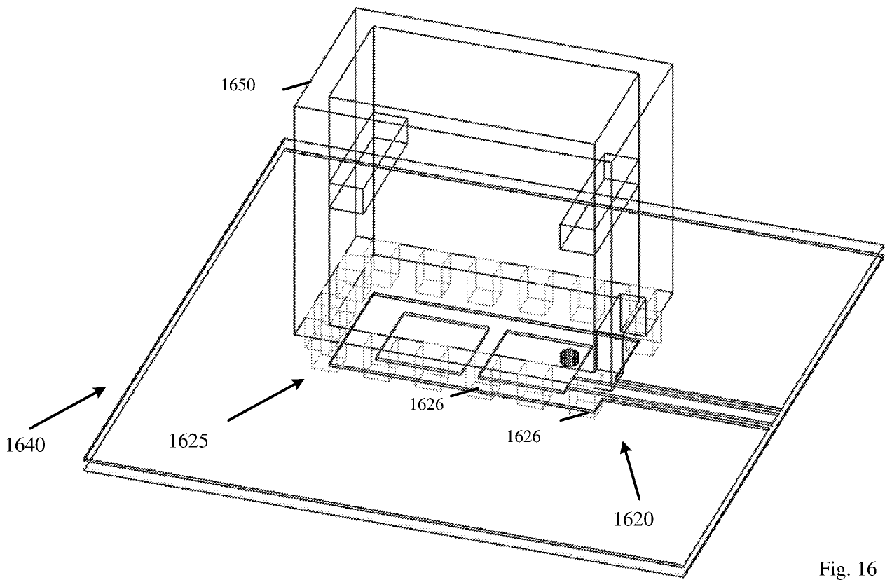

FIG. 16 is a schematic illustration a PCB-to-WG transition 1620, in accordance with some demonstrative aspects.

For example, PCB-to-waveguide transition 1420 (FIG. 14) may include one or more elements of PCB-to-WG transition 1620, and/or may perform one or more operations and/or functionalities of PCB-to-WG transition 1620.

In some demonstrative aspects, as shown in FIG. 16, PCB-to-WG transition 1620 may include a periodic pin structure 1625 including a plurality of pins 1626.

In some demonstrative aspects, as shown in FIG. 16, the periodic pin structure 1625 may be substantially easily added to the PCB-to-WG transition 1620, for example, such that its high performance can be maintained, e.g., even in case of air gaps between a PCB 1640 and a WG 1650.

For example, the plurality of pins 1626 may not have to touch the PCB 1640, for example, in order for the PCB-to-WG transition 1620 to operate properly.

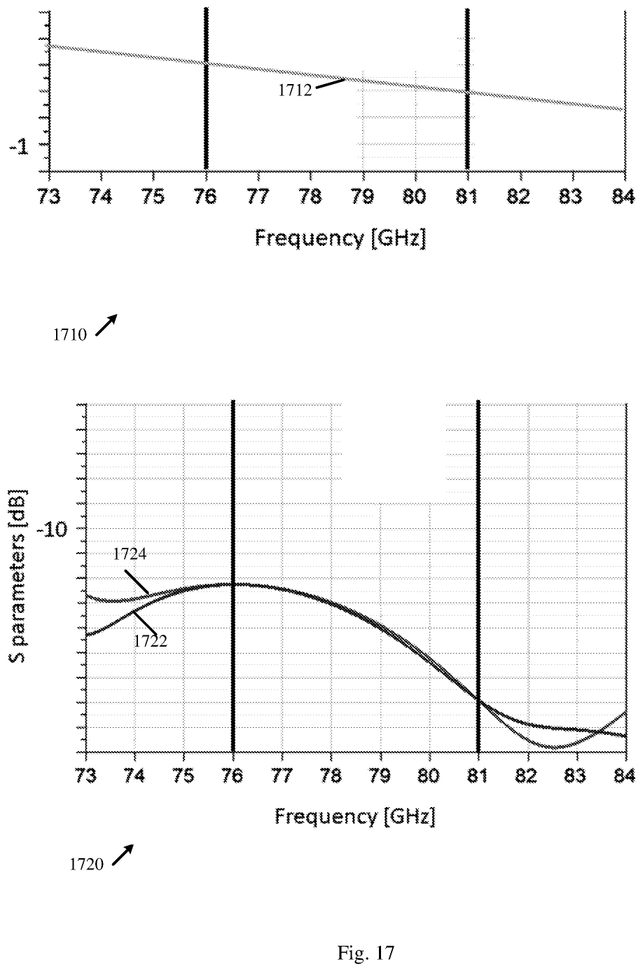

Reference is made to FIG. 17, which schematically illustrates a graph 1710 and a graph 1720 depicting matching curves of a PCB-to-WG transition, in accordance with some demonstrative aspects.

In one example, the graph 1710 and the graph 1720 may depict matching curves of the PCB-to-waveguide transition 1420 (FIG. 14), the PCB-to-waveguide transition 1520 (FIG. 15), and/or the PCB-to-waveguide transition 1620 (FIG. 16).

In one example, the graph 1710 depicts a matching curve 1712 of a transmission coefficient (S21) of the PCB-to-WG transition.

In some demonstrative aspects, as shown in FIG. 17, the PCB-to-WG transition, e.g., the PCB-to-waveguide transition 1420 (FIG. 14), may be configured, for example, such that the transmission coefficient S21 of the PCB-to-WG transition may be greater than −1 dB, for example, for any RF signals in the frequency band of 76-81 GHz.

In one example, the graph 1720 depicts a matching curve 1722 of a first reflection coefficient S11 of the PCB-to-WG transition, and a matching curve 1724 of a second reflection coefficient S22 of the PCB-to-WG transition.

In some demonstrative aspects, as shown in FIG. 17, the PCB-to-WG transition, e.g., the PCB-to-waveguide transition 1420 (FIG. 14), may be configured, for example, such that that both the first reflection coefficient S11 and the second reflection coefficient S22 of the PCB-to-waveguide transition may be less than −10 dB, for example, for any RF signals in the frequency band of 76-81 GHz.

In some demonstrative aspects, as shown in FIG. 17, the PCB-to-WG transition may provide a technical solution to support a wide bandwidth, e.g., easily covering the entire 76-81 GHz automotive radar frequency band.

In some demonstrative aspects, as shown in FIG. 17, the PCB-to-WG transition may provide a technical solution to support excellent matching levels, e.g., better than 10 dB at PCB port 1 (S11) and WG port 2 (S22), and/or low loss (S21), e.g., of less than 1 dB in a frequency bandwidth from 73 GHz to 84 GHz.

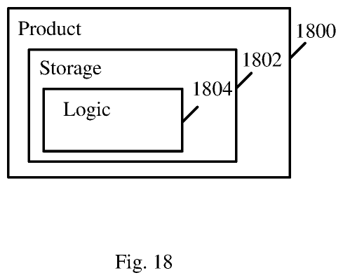

Reference is made to FIG. 18, which schematically illustrates a product of manufacture 1800, in accordance with some demonstrative aspects. Product 1800 may include one or more tangible computer-readable (“machine-readable”) non-transitory storage media 1802, which may include computer-executable instructions, e.g., implemented by logic 1804, operable to, when executed by at least one computer processor, enable the at least one computer processor to implement one or more operations and/or functionalities described with reference to any of the FIGS. 1-17, and/or one or more operations described herein. The phrases “non-transitory machine-readable medium” and “computer-readable non-transitory storage media” may be directed to include all machine and/or computer readable media, with the sole exception being a transitory propagating signal.

In some demonstrative aspects, product 1800 and/or machine-readable storage media 1802 may include one or more types of computer-readable storage media capable of storing data, including volatile memory, non-volatile memory, removable or non-removable memory, erasable or non-erasable memory, writeable or re-writeable memory, and the like. For example, machine-readable storage media 1802 may include, RAM, DRAM, Double-Data-Rate DRAM (DDR-DRAM), SDRAM, static RAM (SRAM), ROM, programmable ROM (PROM), erasable programmable ROM (EPROM), electrically erasable programmable ROM (EEPROM), flash memory (e.g., NOR or NAND flash memory), content addressable memory (CAM), polymer memory, phase-change memory, ferroelectric memory, silicon-oxide-nitride-oxide-silicon (SONOS) memory, a disk, a hard drive, and the like. The computer-readable storage media may include any suitable media involved with downloading or transferring a computer program from a remote computer to a requesting computer carried by data signals embodied in a carrier wave or other propagation medium through a communication link, e.g., a modem, radio or network connection.

In some demonstrative aspects, logic 1804 may include instructions, data, and/or code, which, if executed by a machine, may cause the machine to perform a method, process and/or operations as described herein. The machine may include, for example, any suitable processing platform, computing platform, computing device, processing device, computing system, processing system, computer, processor, or the like, and may be implemented using any suitable combination of hardware, software, firmware, and the like.

In some demonstrative aspects, logic 1804 may include, or may be implemented as, software, a software module, an application, a program, a subroutine, instructions, an instruction set, computing code, words, values, symbols, and the like. The instructions may include any suitable type of code, such as source code, compiled code, interpreted code, executable code, static code, dynamic code, and the like. The instructions may be implemented according to a predefined computer language, manner or syntax, for instructing a processor to perform a certain function. The instructions may be implemented using any suitable high-level, low-level, object-oriented, visual, compiled and/or interpreted programming language, machine code, and the like.

### EXAMPLES

The following examples pertain to further aspects.

Example 1 includes an apparatus comprising a Printed Circuit Board (PCB) comprising one or more single-ended PCB traces configured to route single-ended Radio-Frequency (RF) signals between an integrated circuit and one or more waveguides, wherein first ends of the one or more single-ended PCB traces are to be coupled to the integrated circuit; and one or more PCB-to-waveguide transitions configured to couple second ends of the one or more single-ended PCB traces to the one or more waveguides, wherein a PCB-to-waveguide transition of the one or more PCB-to-waveguide transitions comprises a PCB probe connected to a second end of a single-ended PCB trace of the one or more single-ended PCB traces, the PCB probe configured to couple RF energy of the single-ended RF signals between the single-ended PCB trace and a waveguide of the one or more waveguides; and a via configured to electrically connect the PCB probe to a ground layer of the PCB.

Example 2 includes the subject matter of Example 1, and optionally, wherein the PCB-to-waveguide transition is configured as a PCB-to-narrow-waveguide-side transition configured to couple the single-ended PCB trace to the waveguide via a narrow side of a rectangular shape of the waveguide.

Example 3 includes the subject matter of Example 1 or 2, and optionally, wherein the second end of the single-ended PCB trace is connected to a trace-probe segment of a side of the PCB probe, wherein the second end of the single-ended PCB trace is substantially perpendicular to the trace-probe segment.

Example 4 includes the subject matter of any one of Examples 1-3, and optionally, wherein the second end of the single-ended PCB trace is connected to a trace-probe segment of a side of the PCB probe, wherein the trace-probe segment is proximal to a vertex of the PCB probe.

Example 5 includes the subject matter of Example 4, and optionally, wherein the trace-probe segment is proximal to a first vertex at a first end of the side of the PCB probe, wherein the via is proximal to a second vertex at a second end of the side of the PCB probe.

Example 6 includes the subject matter of any one of Examples 1-5, and optionally, wherein the second end of the single-ended PCB trace is connected to a trace-probe segment of a side of the PCB probe, wherein the trace-probe segment is on a first side of an axis through a midpoint of the side of the PCB probe, wherein the via is on a second side of the axis.

Example 7 includes the subject matter of any one of Examples 1-6, and optionally, wherein the PCB-to-waveguide transition comprises a first PCB probe having a first side connected to the second end of the single-ended PCB trace, wherein the via is configured to electrically connect the first PCB probe to the ground layer of the PCB; and a second PCB probe spaced apart from a second side of the first PCB probe opposite to the first side of the first PCB probe.

Example 8 includes the subject matter of any one of Examples 1-7, and optionally, wherein the one or more single-ended PCB traces comprises a plurality of single-ended PCB traces to route the single-ended RF signals between the integrated circuit and a plurality of waveguides.

Example 9 includes the subject matter of Example 8, and optionally, wherein the plurality of single-ended PCB traces are arranged on the PCB according to a trace arrangement configured to couple second ends of the plurality of single-ended PCB traces to narrow sides of the plurality of waveguides.

Example 10 includes the subject matter of any one of Examples 1-9, and optionally, wherein the via is configured to tunnel reverse RF signals between the PCB probe and the ground layer, wherein the reverse RF signals are in a direction opposite to the single-ended RF signals routed via the single-ended PCB trace.

Example 11 includes the subject matter of any one of Examples 1-10, and optionally, wherein the via is configured to provide a functionality of an RF balancing unit (balun) to match between differential RF signals of the PCB probe and the single-ended RF signals of the single-ended PCB trace.

Example 12 includes the subject matter of any one of Examples 1-11, and optionally, wherein the PCB probe is connected to a single single-ended PCB trace of the one or more single-ended PCB traces.

Example 13 includes the subject matter of any one of Examples 1-12, and optionally, wherein the PCB comprises a metal layer comprising the one or more single-ended PCB traces and the PCB probe.

Example 14 includes the subject matter of any one of Examples 1-13, and optionally, wherein the PCB probe comprises a probe patch.

Example 15 includes the subject matter of Example 14, and optionally, wherein the probe patch comprises a rectangular probe patch.

Example 16 includes the subject matter of any one of Examples 1-15, and optionally, wherein the PCB-to-waveguide transition is configured to couple the single-ended PCB trace to an end of the waveguide.

Example 17 includes the subject matter of any one of Examples 1-16, and optionally, wherein the PCB-to-waveguide transition is configured such that a transmission coefficient (S21) of the PCB-to-waveguide transition is greater than −1 decibel (dB) for any RF signals in a frequency band having a frequency bandwidth of at least 3 Gigahertz (GHz).

Example 18 includes the subject matter of any one of Examples 1-17, and optionally, wherein the PCB-to-waveguide transition is configured such that a transmission coefficient (S21) of the PCB-to-waveguide transition is greater than −1 decibel (dB) for any RF signals in a frequency band having a frequency bandwidth of at least 5 Gigahertz (GHz).

Example 19 includes the subject matter of any one of Examples 1-18, and optionally, wherein the PCB-to-waveguide transition is configured such that a transmission coefficient (S21) of the PCB-to-waveguide transition is greater than −1 decibel (dB) for any RF signals in a frequency band of 76-81 Gigahertz (GHz).

Example 20 includes the subject matter of any one of Examples 1-19, and optionally, wherein the PCB-to-waveguide transition is configured such that both a first reflection coefficient (S11) and a second reflection coefficient (S22) of the PCB-to-waveguide transition are less than −10 decibel (dB) for any RF signals in a frequency band having a frequency bandwidth of at least 3 Gigahertz (GHz)

Example 21 includes the subject matter of any one of Examples 1-20, and optionally, wherein the PCB-to-waveguide transition is configured such that both a first reflection coefficient (S11) and a second reflection coefficient (S22) of the PCB-to-waveguide transition are less than −10 decibel (dB) for any RF signals in a frequency band having a frequency bandwidth of at least 5 Gigahertz (GHz)

Example 22 includes the subject matter of any one of Examples 1-21, and optionally, wherein the PCB-to-waveguide transition is configured such that both a first reflection coefficient (S11) and a second reflection coefficient (S22) of the PCB-to-waveguide transition are less than −10 decibel (dB) for any RF signals in a frequency band of 76-81 Gigahertz (GHz).

Example 23 includes the subject matter of any one of Examples 1-22, and optionally, wherein the one or more single-ended PCB traces and the one or more PCB-to-waveguide transitions are configured to route the single-ended RF signals at a frequency above 70 Gigahertz (GHz).

Example 24 includes the subject matter of any one of Examples 1-23, and optionally, wherein the one or more single-ended PCB traces and the one or more PCB-to-waveguide transitions are configured to route the single-ended RF signals in a frequency band of 76-81 Gigahertz (GHz).

Example 25 includes the subject matter of any one of Examples 1-24, and optionally, comprising the integrated circuit connected to the one or more single-ended PCB traces.

Example 26 includes the subject matter of any one of Examples 1-25, and optionally, comprising the one or more waveguides, and one or more waveguide antennas at ends of the one or more waveguides.

Example 27 includes the subject matter of Example 26, and optionally, comprising a radar device, the radar device comprising one or more Transmit (Tx) antennas, and one or more Receive (Rx) antennas, and a processor to generate radar information based on radar Rx signals received by the one or more Rx antennas based on radar Tx signals transmitted by the one or more Tx antennas, wherein the one or more waveguide antennas comprise one or more respective antennas of the one or more Rx antennas or the one or more Tx antennas.

Example 28 includes the subject matter of Example 27, and optionally, comprising a vehicle, the vehicle comprising the radar device, and a system controller to control one or more systems of the vehicle based on the radar information.

Example 29 includes a device comprising the apparatus of any of Examples 1-26 and a wireless communication interface to communicate wireless communication signals via the one or more waveguides.

Example 30 includes a vehicle comprising the apparatus of any of Examples 1-26.

Example 31 includes an apparatus comprising means for performing any of the described operations of any of Examples 1-26.

Example 32 includes a machine-readable medium that stores instructions for execution by a processor to perform any of the described operations of any of Examples 1-26.

Example 33 comprises a product comprising one or more tangible computer-readable non-transitory storage media comprising computer-executable instructions operable to, when executed by at least one processor, enable the at least one processor to cause a device to perform any of the described operations of any of Examples 1-26.

Example 34 includes an apparatus comprising a memory; and processing circuitry configured to perform any of the described operations of any of Examples 1-26.

Example 35 includes a method including any of the described operations of any of Examples 1-26.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the disclosure.

1.-29. (canceled)

30. An apparatus comprising:
a Printed Circuit Board (PCB) comprising:
one or more single-ended PCB traces configured to route single-ended Radio-Frequency (RF) signals between an integrated circuit and one or more waveguides, wherein first ends of the one or more single-ended PCB traces are to be coupled to the integrated circuit; and
one or more PCB-to-waveguide transitions configured to couple second ends of the one or more single-ended PCB traces to the one or more waveguides, wherein a PCB-to-waveguide transition of the one or more PCB-to-waveguide transitions comprises:
a PCB probe connected to a second end of a single-ended PCB trace of the one or more single-ended PCB traces, the PCB probe configured to couple RF energy of the single-ended RF signals between the single-ended PCB trace and a waveguide of the one or more waveguides; and
a via configured to electrically connect the PCB probe to a ground layer of the PCB.

31. The apparatus of claim 30, wherein the PCB-to-waveguide transition is configured as a PCB-to-narrow-waveguide-side transition configured to couple the single-ended PCB trace to the waveguide via a narrow side of a rectangular shape of the waveguide.

32. The apparatus of claim 30, wherein the second end of the single-ended PCB trace is connected to a trace-probe segment of a side of the PCB probe, wherein the second end of the single-ended PCB trace is substantially perpendicular to the trace-probe segment.

33. The apparatus of claim 30, wherein the second end of the single-ended PCB trace is connected to a trace-probe segment of a side of the PCB probe, wherein the trace-probe segment is proximal to a vertex of the PCB probe.

34. The apparatus of claim 33, wherein the trace-probe segment is proximal to a first vertex at a first end of the side of the PCB probe, wherein the via is proximal to a second vertex at a second end of the side of the PCB probe.

35. The apparatus of claim 30, wherein the second end of the single-ended PCB trace is connected to a trace-probe segment of a side of the PCB probe, wherein the trace-probe segment is on a first side of an axis through a midpoint of the side of the PCB probe, wherein the via is on a second side of the axis.

36. The apparatus of claim 30, wherein the PCB-to-waveguide transition comprises:
a first PCB probe having a first side connected to the second end of the single-ended PCB trace, wherein the via is configured to electrically connect the first PCB probe to the ground layer of the PCB; and
a second PCB probe spaced apart from a second side of the first PCB probe opposite to the first side of the first PCB probe.

37. The apparatus of claim 30, wherein the one or more single-ended PCB traces comprises a plurality of single-ended PCB traces to route the single-ended RF signals between the integrated circuit and a plurality of waveguides.

38. The apparatus of claim 37, wherein the plurality of single-ended PCB traces are arranged on the PCB according to a trace arrangement configured to couple second ends of the plurality of single-ended PCB traces to narrow sides of the plurality of waveguides.

39. The apparatus of claim 30, wherein the via is configured to tunnel reverse RF signals between the PCB probe and the ground layer, wherein the reverse RF signals are in a direction opposite to the single-ended RF signals routed via the single-ended PCB trace.

40. The apparatus of claim 30, wherein the via is configured to provide a functionality of an RF balancing unit (balun) to match between differential RF signals of the PCB probe and the single-ended RF signals of the single-ended PCB trace.

41. The apparatus of claim 30, wherein the PCB probe is connected to a single single-ended PCB trace of the one or more single-ended PCB traces.

42. The apparatus of claim 30, wherein the PCB comprises a metal layer comprising the one or more single-ended PCB traces and the PCB probe.

43. The apparatus of claim 30, wherein the PCB probe comprises a probe patch.

44. The apparatus of claim 43, wherein the probe patch comprises a rectangular probe patch.

45. The apparatus of claim 30, wherein the PCB-to-waveguide transition is configured to couple the single-ended PCB trace to an end of the waveguide.

46. The apparatus of claim 30, wherein the PCB-to-waveguide transition is configured such that a transmission coefficient (S21) of the PCB-to-waveguide transition is greater than −1 decibel (dB) for any RF signals in a frequency band having a frequency bandwidth of at least 3 Gigahertz (GHz).

47. The apparatus of claim 30, wherein the PCB-to-waveguide transition is configured such that a transmission coefficient (S21) of the PCB-to-waveguide transition is greater than −1 decibel (dB) for any RF signals in a frequency band of 76-81 Gigahertz (GHz).

48. The apparatus of claim 30, wherein the PCB-to-waveguide transition is configured such that both a first reflection coefficient (S11) and a second reflection coefficient (S22) of the PCB-to-waveguide transition are less than −10 decibel (dB) for any RF signals in a frequency band having a frequency bandwidth of at least 3 Gigahertz (GHz).

49. The apparatus of claim 30, wherein the PCB-to-waveguide transition is configured such that both a first reflection coefficient (S11) and a second reflection coefficient (S22) of the PCB-to-waveguide transition are less than −10 decibel (dB) for any RF signals in a frequency band of 76-81 Gigahertz (GHz).

50. The apparatus of claim 30 comprising the integrated circuit connected to the one or more single-ended PCB traces.

51. The apparatus of claim 30 comprising the one or more waveguides, and one or more waveguide antennas at ends of the one or more waveguides.

52. The apparatus of claim 51 comprising a radar device, the radar device comprising one or more Transmit (Tx) antennas, one or more Receive (Rx) antennas, and a processor to generate radar information based on radar Rx signals received by the one or more Rx antennas based on radar Tx signals transmitted by the one or more Tx antennas, wherein the one or more waveguide antennas comprise one or more respective antennas of the one or more Rx antennas or the one or more Tx antennas.

53. A vehicle comprising:
a system controller configured to control one or more vehicular systems of the vehicle based on radar information; and
a radar system configured to provide the radar information to the system controller, the radar system comprising:
one or more Transmit (Tx) antennas;
one or more Receive (Rx) antennas;
one or more waveguides connected to one or more antennas of the one or more Tx antennas or the one or more Rx antennas;
an integrated circuit to process single-ended Radio-Frequency (RF) signals; and
a Printed Circuit Board (PCB) comprising:
one or more single-ended PCB traces configured to route the single-ended RF signals between the integrated circuit and the one or more waveguides, wherein first ends of the one or more single-ended PCB traces are coupled to the integrated circuit; and
one or more PCB-to-waveguide transitions configured to couple second ends of the one or more single-ended PCB traces to the one or more waveguides, wherein a PCB-to-waveguide transition of the one or more PCB-to-waveguide transitions comprises:
a PCB probe connected to a second end of a single-ended PCB trace of the one or more single-ended PCB traces, the PCB probe configured to couple RF energy of the single-ended RF signals between the single-ended PCB trace and a waveguide of the one or more waveguides; and
a via configured to electrically connect the PCB probe to a ground layer of the PCB.

54. The vehicle of claim 53, wherein the PCB-to-waveguide transition is configured as a PCB-to-narrow-waveguide-side transition configured to couple the single-ended PCB trace to the waveguide via a narrow side of a rectangular shape of the waveguide.
